(19) United States
(12) Patent Application Publication
(10) Pub. No.: US 2026/0019040 A1
(43) Pub. Date: Jan. 15, 2026

(54) TRACKER CIRCUIT, COMMUNICATION DEVICE, AND VOLTAGE SUPPLY METHOD

(71) Applicant: Murata Manufacturing Co., Ltd., Nagaokakyo-shi (JP)

(72) Inventors: Takeshi KOGURE, Nagaokakyo-shi (JP); Taichi YAMAGUCHI, Nagaokakyo-shi (JP); Atsuya HIRONO, Nagaokakyo-shi (JP); Naohide TOMITA, Nagaokakyo-shi (JP); YUUKI FUKUDA, Nagaokakyo-shi (JP)

(21) Appl. No.: 19/333,869

(22) Filed: Sep. 19, 2025

Related U.S. Application Data
(63) Continuation of application No. PCT/JP2024/004332, filed on Feb. 8, 2024.

(30) Foreign Application Priority Data
Mar. 27, 2023 (JP) 2023-049968

(51) Int. Cl. H03F 1/02; H03F 3/24; H04B 1/04

(52) U.S. Cl. CPC H03F 1/0233; H03F 3/245; H04B 1/04; H03F 2200/105; H03F 2200/451

(57) ABSTRACT

A tracker circuit is provided that includes a switched-capacitor circuit that generates, from a first input voltage, a first output voltage and a second output voltage that is lower than the first output voltage; a switched-capacitor circuit that generates, from the first output voltage and the second output voltage, a third output voltage that is lower than the first output voltage and higher than the second output voltage; and a supply modulator that selectively outputs, to a power amplifier, at least one of a plurality of discrete voltages that includes the first output voltage, the second output voltage, and the third output voltage.

### CROSS REFERENCE TO RELATED APPLICATIONS

This application is a continuation of International Application No. PCT/JP2024/004332, filed Feb. 8, 2024, which claims priority to Japanese Patent Application No. Application No. 2023-049968, filed Mar. 27, 2023, the contents of each of which are hereby incorporated by reference in their entireties.

### TECHNICAL FIELD

The present disclosure relates to a tracker circuit, a communication device, and a voltage supply method.

### BACKGROUND

In recent years, envelope tracking (ET) has been applied to power amplifier (PA) circuits in order to improve power-added efficiency (PAE). For example, U.S. Pat. No. 8,829,993 discloses a technology of digital envelope tracking (D-ET) for selectively supplying a plurality of discrete voltages in accordance with an envelope signal.

In the 5G standard for Internet of Things (IoT) (for example, Reduced Capability (RedCap)), further improvement in power efficiency is requested to reduce power consumption.

### SUMMARY OF THE INVENTION

Accordingly, the exemplary aspects of the present disclosure provide a tracker circuit, a communication device, and a voltage supply method that improve power efficiency in a D-ET mode.

According to an exemplary aspect, a tracker circuit is provided that includes a first switched-capacitor circuit configured to generate, from a first input voltage, a first output voltage and a second output voltage that is lower than the first output voltage; a second switched-capacitor circuit configured to generate, from the first output voltage and the second output voltage, a third output voltage that is lower than the first output voltage and higher than the second output voltage; and a supply modulator configured to selectively output, to a power amplifier, at least one discrete voltage of a plurality of discrete voltages that includes the first output voltage, the second output voltage, and the third output voltage.

In another exemplary aspect, a tracker circuit is provided that includes a first switched-capacitor circuit including a first input terminal configured to receive a first input voltage, and a first output terminal and a second output terminal that are configured to output a first output voltage and a second output voltage, respectively, that are generated from the first input voltage, the second output voltage being lower than the first output voltage; a second switched-capacitor circuit including a second input terminal and a third input terminal respectively connected to the first output terminal and the second output terminal, and a third output terminal that is configured to output a third output voltage generated from the first output voltage and the second output voltage, the third output voltage being lower than the first output voltage and higher than the second output voltage; and a supply modulator including a fourth input terminal, a fifth input terminal, and a sixth input terminal respectively connected to the first output terminal, the second output terminal, and the third output terminal, and a fourth output terminal connected to a power amplifier.

In another exemplary aspect, a communication device is provided that includes the above-described tracker circuit; a signal processing circuit configured to process a radio frequency signal; and a radio frequency circuit including the power amplifier and configured to transmit the radio frequency signal between the signal processing circuit and an antenna.

In yet another exemplary aspect, a voltage supply method is provided that includes generating a first output voltage and a second output voltage from an input voltage by using a first switched-capacitor circuit; generating a third output voltage from the first output voltage and the second output voltage by using a second switched-capacitor circuit, the third output voltage being lower than the first output voltage and higher than the second output voltage; and selectively supplying, to a power amplifier, at least one of a plurality of discrete voltages including the first output voltage, the second output voltage, and the third output voltage.

According to the exemplary aspects of the present disclosure, power efficiency is improved in a D-ET mode.

### BRIEF DESCRIPTION OF DRAWINGS

FIG. 1A is a graph illustrating an example of transition of a power supply voltage in an average power tracking (APT) mode.

FIG. 1B is a graph illustrating an example of transition of a power supply voltage in an analog envelope tracking (A-ET) mode.

FIG. 1C is a graph illustrating an example of transition of a power supply voltage in a digital envelope tracking (D-ET) mode.

FIG. 2 is a circuit configuration diagram of a communication device according to a first exemplary embodiment.

FIG. 3 is a circuit configuration diagram of a pre-regulator circuit according to the first exemplary embodiment.

FIG. 4 is a circuit configuration diagram of a tracker circuit according to the first exemplary embodiment.

FIG. 5 is a flowchart illustrating a voltage supply method according to the first exemplary embodiment.

FIG. 6 is a diagram illustrating a plurality of discrete voltages that can be supplied in the first exemplary embodiment and comparative examples 1 and 2.

FIG. 7 is a partial circuit configuration diagram of a tracker circuit according to a second exemplary embodiment.

FIG. 8 is a diagram illustrating a plurality of discrete voltages that can be supplied in the second exemplary embodiment and comparative examples 2 and 3.

FIG. 9 is a partial circuit configuration diagram of a tracker circuit according to a third exemplary embodiment.

FIG. 10 is a diagram illustrating a plurality of discrete voltages that can be supplied in the third exemplary embodiment and comparative example 3.

FIG. 11 is a partial circuit configuration diagram of a tracker circuit according to a fourth exemplary embodiment.

FIG. 12 is a diagram illustrating a plurality of discrete voltages that can be supplied in the fourth exemplary embodiment and comparative example 3.

FIG. 13 is a circuit configuration diagram of a pre-regulator circuit according to a fifth exemplary embodiment.

FIG. 14 is a partial circuit configuration diagram of a tracker circuit according to the fifth exemplary embodiment.

FIG. 15 is a diagram illustrating a plurality of discrete voltages that can be supplied in the fifth exemplary embodiment and comparative example 3.

FIG. 16 is a partial circuit configuration diagram of a tracker circuit according to a sixth exemplary embodiment.

FIG. 17 is a diagram illustrating a plurality of discrete voltages that can be supplied in the sixth exemplary embodiment and comparative example 3.

### DETAILED DESCRIPTION OF EMBODIMENTS

Hereinafter, exemplary embodiments of the present disclosure will be described in detail with reference to the drawings. The embodiments described below each illustrate a general or specific example. The numerical values, shapes, materials, constituent elements, the disposition and connection manner of the constituent elements, and so forth described in the following embodiments are merely examples and are not intended to limit the present disclosure.

The drawings are schematic diagrams drawn with emphasis, omission, or ratio adjustment performed as appropriate in order to illustrate the exemplary aspects of the present disclosure. Thus, it is noted that the illustration therein is not necessarily strict, and may be different from actual shapes, positional relationships, and ratios. In the drawings, components that are substantially the same are denoted by the same reference numerals, and a repeated description thereof may be omitted or simplified.

In a circuit configuration, the term “connected” includes not only a direct connection using a connection terminal and/or a wiring conductor, but also an electrical connection via another circuit element. Moreover, the term “directly connected” can indicate directly connected using a connection terminal and/or a wiring conductor without interposing another circuit element. The expression “C is connected between A and B” indicates that one end of C is connected to A and the other end of C is connected to B, and indicates that C is disposed in series to a path connecting A and B. The expression “path connecting A and B” refers to a path composed of a conductor that electrically connects A to B.

In the following description, a “terminal” refers to a point at which a conductor in an element terminates. In a case where the impedance of a conductor between elements is sufficiently low, a terminal is interpreted as not only a single point but also any point on the conductor between the elements or the entire conductor.

In addition, terms indicating the relationships between elements, such as “parallel” and “perpendicular”, terms indicating the shapes of elements, such as “rectangular”, and numerical ranges do not represent only strict meanings, but include substantially equivalent ranges, for example, an error of about several percent.

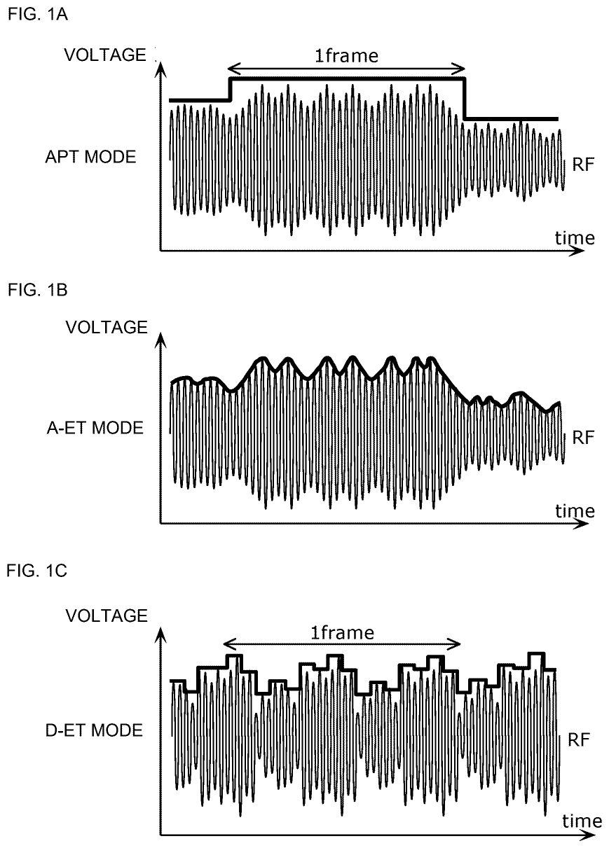

First, a description will be given of tracking modes of supplying a power amplifier (PA) with a power supply voltage dynamically regulated based on a radio frequency (RF) signal over time, which are techniques of amplifying the RF signal with high efficiency. A tracking mode is a mode of dynamically regulating the power supply voltage to be applied to a PA. Among several types of tracking modes, an average power tracking (APT) mode, an analog envelope tracking (A-ET) mode, and a digital envelope tracking (D-ET) mode will be described here with reference to FIG. 1A to FIG. 1C. In FIG. 1A to FIG. 1C, the horizontal axis represents time, and the vertical axis represents voltage. A thick solid line represents a power supply voltage, and a thin solid line (e.g., a waveform) represents a modulated signal.

FIG. 1A is a graph illustrating an example of transition of a power supply voltage in the APT mode. In the APT mode, the power supply voltage is varied, based on an average power, to a plurality of discrete voltage levels in units of one frame.

For purposes of this disclosure, a frame refers to a unit forming an RF signal (e.g., a modulated signal). For example, in 5th Generation New Radio (5G NR) and Long Term Evolution (LTE), a frame includes ten subframes, each subframe includes a plurality of slots, and each slot is formed by a plurality of symbols. The subframe has a length of 1 ms, and the frame has a length of 10 ms.

A mode of varying a voltage level in units of one frame or in units larger than one frame based on an average power is referred to as an “APT mode”, which is distinguished from a mode of varying a voltage level in units smaller than one frame (for example, in units of subframes, slots, or symbols).

FIG. 1B is a graph illustrating an example of transition of a power supply voltage in the A-ET mode. In the A-ET mode, the power supply voltage is continuously varied based on an envelope signal, and thus the envelope of a modulated signal is tracked.

The envelope signal is a signal indicating the envelope of a modulated signal. An envelope value is represented by, for example, the square root of (I²+Q²). (I, Q) represents a constellation point herein. The constellation point is a point representing a digitally modulated signal on a constellation diagram. (I, Q) is determined by a baseband integrated circuit (BBIC), for example, based on transmission information.

FIG. 1C is a graph illustrating an example of transition of a power supply voltage in the D-ET mode. In the D-ET mode, the power supply voltage is varied, based on an envelope signal, to a plurality of discrete voltage levels within one frame, and thus the envelope of a modulated signal is tracked. That is, in D-ET, the power supply voltage varies at a time interval shorter than in APT.

### First Exemplary Embodiment

Hereinafter, a first exemplary embodiment will be described.

### [1.1 Circuit Configuration of Communication Device 7]

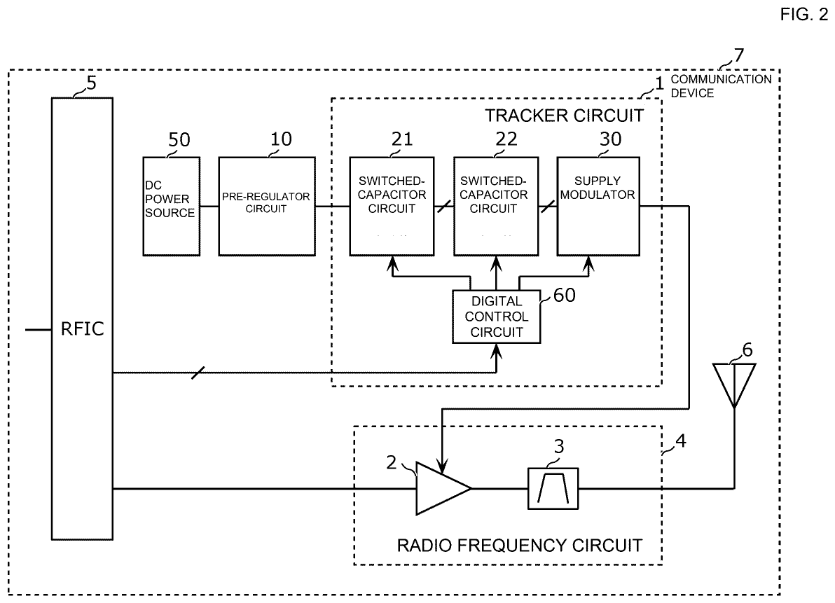

First, the circuit configuration of a communication device 7 according to the present embodiment will be described with reference to FIG. 2. FIG. 2 is a circuit configuration diagram of the communication device 7 according to the present embodiment.

FIG. 2 illustrates an exemplary circuit configuration. The communication device 7 can be implemented by using any of a wide variety of circuit implementations and circuit techniques. Thus, it should be appreciated that the description of the communication device 7 provided below is not to be construed in a limiting manner.

The communication device 7 according to the present embodiment corresponds to user equipment (UE) in a cellular network (also referred to as a “mobile network”) and is typically a mobile phone, a smartphone, a tablet computer, a wearable device, or the like. The communication device 7 may be an Internet of Things (IoT) sensor device, a medical/health-care device, a vehicle, an unmanned aerial vehicle (UAV) (a so-called drone), or an automated guided vehicle (AGV). The communication device 7 may function as a base station (BS) in a cellular network.

As illustrated in FIG. 2, the communication device 7 includes a tracker circuit 1, a radio frequency (RF) circuit 4, a radio frequency integrated circuit (RFIC) 5, an antenna 6, a pre-regulator circuit 10, and a direct current (DC) power source 50.

The tracker circuit 1 is configured to supply a plurality of discrete voltages to a power amplifier (PA) 2 in the D-ET mode. Furthermore, the tracker circuit 1 may supply a plurality of discrete voltages to the PA 2 in the APT mode. As illustrated in FIG. 2, the tracker circuit 1 includes switched-capacitor circuits 21 and 22, a supply modulator 30, and a digital control circuit 60.

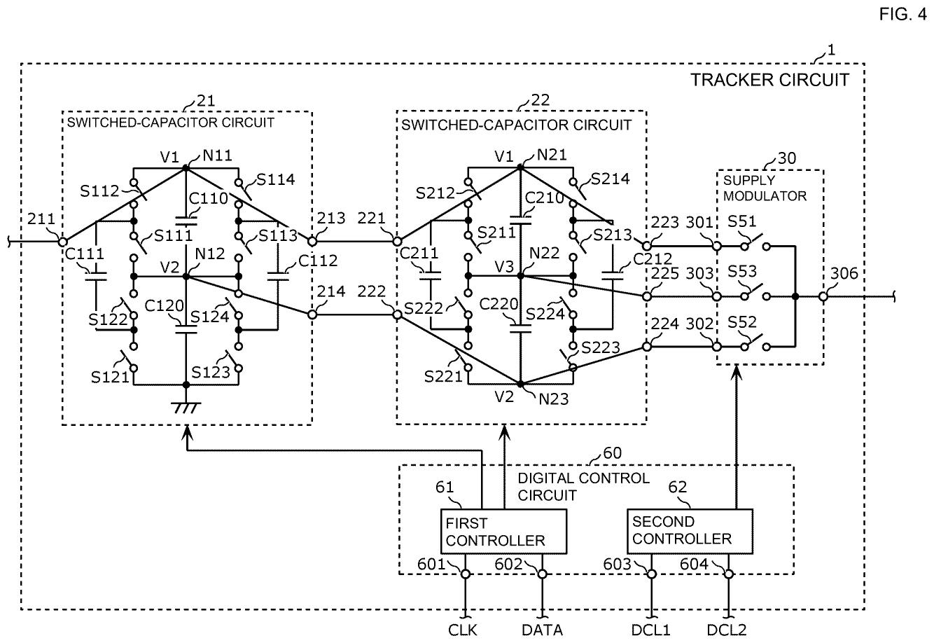

The switched-capacitor circuits 21 and 22 are an example of a first switched-capacitor circuit and an example of a second switched-capacitor circuit, respectively, and are configured to generate a plurality of discrete voltages from an input voltage (first input voltage) supplied from the pre-regulator circuit 10. To be specific, the switched-capacitor circuit 21 is configured to generate, from an input voltage, a first output voltage and a second output voltage that is lower than the first output voltage. The switched-capacitor circuit 22 is configured to generate, from the first output voltage and the second output voltage, a third output voltage that is lower than the first output voltage and higher than the second output voltage. For example, the switched-capacitor circuit 22 is configured to generate the third output voltage, based on a difference between the first output voltage and the second output voltage. The circuit configurations of the switched-capacitor circuits 21 and 22 will be described below with reference to FIG. 4.

The supply modulator 30 is configured to selectively output, to the PA 2, at least one of a plurality of discrete voltages including the first output voltage, the second output voltage, and the third output voltage that have been generated by the switched-capacitor circuits 21 and 22. That is, the supply modulator 30 is configured to select at least one voltage from among the plurality of discrete voltages and supplying the selected voltage to the PA 2. The circuit configuration of the supply modulator 30 will be described below with reference to FIG. 4.

The digital control circuit 60 is configured to control, based on a digital control signal from the RFIC 5, the switched-capacitor circuits 21 and 22 and the supply modulator 30. To be specific, the digital control circuit 60 is configured to generate and output a control signal for controlling a switch included in the switched-capacitor circuits 21 and 22 and a control signal for controlling a switch included in the supply modulator 30. The circuit configuration of the digital control circuit 60 will be described below with reference to FIG. 4. The digital control circuit 60 may be omitted from the tracker circuit 1 according to an exemplary aspect.

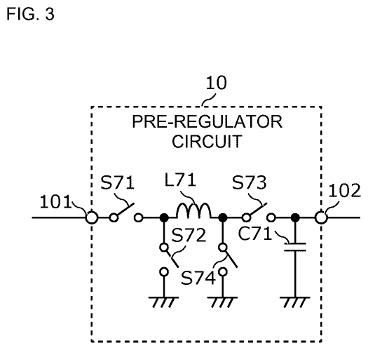

The pre-regulator circuit 10 may also be referred to as a “magnetic regulator” or a “DC-DC converter”. In the present embodiment, the pre-regulator circuit 10 is a one-input one-output buck-boost converter and is configured to convert an output voltage of the DC power source 50 into an input voltage (e.g., a first input voltage) of the switched-capacitor circuit 21. The pre-regulator circuit 10 may be a buck converter or a boost converter. The pre-regulator circuit 10 is configured to change, based on a control signal from the RFIC 5, for example, the input voltage of the switched-capacitor circuit 21. The circuit configuration of the pre-regulator circuit 10 will be described below with reference to FIG. 3.

The DC power source 50 is configured to supply a DC voltage to the pre-regulator circuit 10. The DC power source 50 may be, but is not limited to, a rechargeable battery, for example.

The RF circuit 4 is configured to transmit an RF signal between the RFIC 5 and the antenna 6. As illustrated in FIG. 2, the RF circuit 4 includes the PA 2 and a filter 3.

The PA 2 is connected between the RFIC 5 and the filter 3. The PA 2 is further connected to the tracker circuit 1. The PA 2 is configured to amplify an RF signal supplied from the RFIC 5 by using a plurality of discrete voltages supplied from the tracker circuit 1.

The filter 3 is connected between the PA 2 and the antenna 6. The filter 3 is a band pass filter having a pass band including a predetermined band. The filter 3 may be omitted from the RF circuit 4 according to an exemplary aspect.

The predetermined band is a frequency band for a communication system constructed by using radio access technology (RAT), and is predefined by standardizing bodies (for example, 3rd Generation Partnership Project (3GPP®), Institute of Electrical and Electronics Engineers (IEEE), and so forth). Examples of the communication system include a 5G NR system, an LTE system, and a Wireless Local Area Network (WLAN) system.

The antenna 6 transmits an RF signal received from the RF circuit 4. The antenna 6 may be omitted from the communication device 7 according to an exemplary aspect.

The circuit configuration of the communication device 7 illustrated in FIG. 2 is illustrative and is not restrictive. For example, the communication device 7 may include a baseband signal processing circuit that performs signal processing by using a frequency band lower than the frequency of an RF signal.

### [1.2 Circuit Configuration of Pre-Regulator Circuit 10]

Next, the circuit configuration of the pre-regulator circuit 10 will be described with reference to FIG. 3. FIG. 3 is a circuit configuration diagram of the pre-regulator circuit 10 according to the present embodiment.

FIG. 3 illustrates an exemplary circuit configuration. The pre-regulator circuit 10 can be implemented by using any of a wide variety of circuit implementations and circuit techniques. Thus, it should be appreciated that the description of the pre-regulator circuit 10 provided below is not to be construed in a limiting manner.

The pre-regulator circuit 10 includes an input terminal 101, an output terminal 102, switches S71 to S74, a power inductor L71, and a capacitor C71.

The input terminal 101 is a terminal for receiving a DC voltage from the DC power source 50. The input terminal 101 is connected to the DC power source 50 outside the pre-regulator circuit 10 and is connected to the switch S71 inside the pre-regulator circuit 10.

The output terminal 102 is a terminal for supplying an input voltage (V1) to the switched-capacitor circuit 21. The output terminal 102 is connected to an input terminal 211 of the switched-capacitor circuit 21 outside the pre-regulator circuit 10 and is connected to the switch S73 inside the pre-regulator circuit 10.

The power inductor L71 is an inductor used to raise and lower a DC voltage. One end of the power inductor L71 is connected to the switches S71 and S72, and the other end of the power inductor L71 is connected to the switches S73 and S74.

The switch S71 is connected between the input terminal 101 and the one end of the power inductor L71. In this connection configuration, open/close switching of the switch S71 enables switching between connection and disconnection between the input terminal 101 and the one end of the power inductor L71.

The switch S72 is connected between the one end of the power inductor L71 and ground. In this connection configuration, open/close switching of the switch S72 enables switching between connection and disconnection between the one end of the power inductor L71 and ground.

The switch S73 is connected between the other end of the power inductor L71 and the output terminal 102. In this connection configuration, open/close switching of the switch S73 enables switching between connection and disconnection between the other end of the power inductor L71 and the output terminal 102.

The switch S74 is connected between the other end of the power inductor L71 and ground. In this connection configuration, open/close switching of the switch S74 enables switching between connection and disconnection between the other end of the power inductor L71 and ground.

The capacitor C71 is connected between ground and a path between the switch S73 and the output terminal 102. To be specific, one of the two electrodes of the capacitor C71 is connected to the switch S73 and the output terminal 102, and the other of the two electrodes of the capacitor C71 is connected to ground.

It is noted that the configuration of the pre-regulator circuit 10 illustrated in FIG. 3 is illustrative and is not restrictive. For example, one or some of the switches S71 to S74 may be replaced with a diode. A part or the entirety of the pre-regulator circuit 10 may be included in the tracker circuit 1.

### [1.3 Circuit Configuration of Tracker Circuit 1]

Next, the circuit configuration of the tracker circuit 1 will be described with reference to FIG. 4. FIG. 4 is a circuit configuration diagram of the tracker circuit 1 according to the present embodiment.

FIG. 4 illustrates an exemplary circuit configuration. The tracker circuit 1 can be implemented by using any of a wide variety of circuit implementations and circuit techniques. Thus, it should be appreciated that the description of the tracker circuit 1 provided below is not to be construed in a limiting manner.

As described above, the tracker circuit 1 includes the switched-capacitor circuits 21 and 22, the supply modulator 30, and the digital control circuit 60. The tracker circuit 1 may include a filter circuit (not illustrated) between the supply modulator 30 and the PA 2. In RedCap, use of half duplex-frequency division duplex (HD-FDD) is considered, and there is a possibility that full duplex-frequency division duplex (FD-FDD) is not used. In a case where FD-FDD is not used, the tracker circuit 1 does not include a filter circuit as illustrated in FIG. 4, and thereby the power efficiency of the communication device 7 can be increased.

Hereinafter, the circuit configurations of the switched-capacitor circuits 21 and 22, the supply modulator 30, and the digital control circuit 60 will be described in order.

### [1.3.1 Circuit Configuration of Switched-Capacitor Circuit 21]

First, the circuit configuration of the switched-capacitor circuit 21 will be described with reference to FIG. 4. The switched-capacitor circuit 21 has a ladder circuit configuration. To be specific, the switched-capacitor circuit 21 includes capacitors C110 to C112 and C120, switches S111 to S114 and S121 to S124, the input terminal 211, and output terminals 213 and 214. Energy and electric charge are input from the pre-regulator circuit 10 to a node N11 via the input terminal 211 and withdrawn from nodes N11 and N12 to the switched-capacitor circuit 22 via the output terminals 213 and 214.

The input terminal 211 is an example of a first input terminal and is a terminal for receiving an input voltage (V1) from the pre-regulator circuit 10. The input terminal 211 is connected to the pre-regulator circuit 10 outside the switched-capacitor circuit 21 and is connected to the node N11 inside the switched-capacitor circuit 21.

The input voltage (V1) is an example of a first input voltage and is supplied from the pre-regulator circuit 10.

The output terminal 213 is an example of a first output terminal and is a terminal for supplying an output voltage (V1) to the switched-capacitor circuit 22. The output terminal 213 is connected to the switched-capacitor circuit 22 outside the switched-capacitor circuit 21 and is connected to the node N11 inside the switched-capacitor circuit 21. The output terminal 213 may be integrated with the input terminal 211 in an exemplary aspect.

The output voltage (V1) is an example of a first output voltage and is generated from the input voltage (V1). In the present embodiment, the output voltage (V1) is equal to the input voltage (V1) and is higher than an output voltage (V2).

The output terminal 214 is an example of a second output terminal and is a terminal for supplying the output voltage (V2) to the switched-capacitor circuit 22. The output terminal 214 is connected to the switched-capacitor circuit 22 outside the switched-capacitor circuit 21 and is connected to the node N12 inside the switched-capacitor circuit 21.

The output voltage (V2) is an example of a second output voltage and is generated from the input voltage (V1). In the present embodiment, the output voltage (V2) is lower than the output voltage (V1).

The capacitors C111 and C112 are flying capacitors (also referred to as “transfer capacitors”) and can be configured to raise and/or lower the input voltage (V1) supplied from the pre-regulator circuit 10. To be more specific, the capacitors C111 and C112 cause electric charge to move from/to the capacitors C111 and C112 to/from the nodes N11 and N12 and ground so that the voltages V1 and V2 satisfying (V1−V2):(V2−VG)=1:1 and V1>V2>VG are maintained at the two nodes N11 and N12. Here, VG represents a ground potential.

One of the two electrodes of the capacitor C111 is connected to one end of the switch S111 and one end of the switch S112. The other of the two electrodes of the capacitor C111 is connected to one end of the switch S121 and one end of the switch S122.

One of the two electrodes of the capacitor C112 is connected to one end of the switch S113 and one end of the switch S114. The other of the two electrodes of the capacitor C112 is connected to one end of the switch S123 and one end of the switch S124.

In an exemplary aspect, the capacitors C111 and C112 can be charged and discharged in a complementary manner as a result of a first phase and a second phase being repeated.

To be specific, in the first phase, the switches S112, S113, S122, and S123 are closed, whereas the switches S111, S114, S121, and S124 are opened. Accordingly, the one of the two electrodes of the capacitor C111 is connected to the node N11, the other of the two electrodes of the capacitor C111 and the one of the two electrodes of the capacitor C112 are connected to the node N12, and the other of the two electrodes of the capacitor C112 is connected to ground.

On the other hand, in the second phase, the switches S112, S113, S122, and S123 are opened, whereas the switches S111, S114, S121, and S124 are closed. Accordingly, the one of the two electrodes of the capacitor C112 is connected to the node N11, the other of the two electrodes of the capacitor C112 and the one of the two electrodes of the capacitor C111 are connected to the node N12, and the other of the two electrodes of the capacitor C111 is connected to ground.

As a result of the first phase and the second phase being repeated, for example, when one of the capacitors C111 and C112 is charged through the node N11, the other of the capacitors C111 and C112 can be discharged to the capacitor C120. In short, the capacitors C111 and C112 can be charged and discharged in a complementary manner. The capacitors C110 and C120 can be configured as smoothing capacitors and are used to hold and smooth the output voltages (V1 and V2) at the nodes N11 and N12.

The capacitor C110 is connected between the nodes N11 and N12. To be specific, one of the two electrodes of the capacitor C110 is connected to the node N11. On the other hand, the other of the two electrodes of the capacitor C110 is connected to the node N12.

The capacitor C120 is connected between the node N12 and ground. To be specific, one of the two electrodes of the capacitor C120 is connected to the node N12. On the other hand, the other of the two electrodes of the capacitor C120 is connected to ground.

The switch S111 is connected between the capacitor C111 and the node N12. To be specific, the one end of the switch S111 is connected to the one of the two electrodes of the capacitor C111. On the other hand, the other end of the switch S111 is connected to the node N12.

The switch S112 is connected between the capacitor C111 and the node N11. To be specific, the one end of the switch S112 is connected to the one of the two electrodes of the capacitor C111. On the other hand, the other end of the switch S112 is connected to the node N11.

The switch S121 is connected between the capacitor C111 and ground. To be specific, the one end of the switch S121 is connected to the other of the two electrodes of the capacitor C111. On the other hand, the other end of the switch S121 is connected to ground.

The switch S122 is connected between the capacitor C111 and the node N12. To be specific, the one end of the switch S122 is connected to the other of the two electrodes of the capacitor C111. On the other hand, the other end of the switch S122 is connected to the node N12.

The switch S113 is connected between the capacitor C112 and the node N12. To be specific, the one end of the switch S113 is connected to the one of the two electrodes of the capacitor C112. On the other hand, the other end of the switch S113 is connected to the node N12. That is, the other end of the switch S113 is connected to the other end of the switch S111 and the other end of the switch S122.

The switch S114 is connected between the capacitor C112 and the node N11. To be specific, the one end of the switch S114 is connected to the one of the two electrodes of the capacitor C112. On the other hand, the other end of the switch S114 is connected to the node N11. That is, the other end of the switch S114 is connected to the other end of the switch S112.

The switch S123 is connected between the capacitor C112 and ground. To be specific, the one end of the switch S123 is connected to the other of the two electrodes of the capacitor C112. On the other hand, the other end of the switch S123 is connected to ground.

The switch S124 is connected between the capacitor C112 and the node N12. To be specific, the one end of the switch S124 is connected to the other of the two electrodes of the capacitor C112. On the other hand, the other end of the switch S124 is connected to the node N12. That is, the other end of the switch S124 is connected to the other end of the switch S111, the other end of the switch S122, and the other end of the switch S113.

A first set of switches including the switches S112, S113, S122, and S123 and a second set of switches including the switches S111, S114, S121, and S124 are switched between open and close in a complementary manner based on a control signal from the digital control circuit 60. To be specific, in the first phase, the switches in the first set are closed whereas the switches in the second set are opened. On the other hand, in the second phase, the switches in the first set are opened whereas the switches in the second set are closed.

For example, in one of the first phase and the second phase, charging from the capacitor C111 to the capacitors C110 and C120 is performed, and in the other of the first phase and the second phase, charging from the capacitor C112 to the capacitors C110 and C120 is performed. In other words, because the capacitors C110 and C120 are constantly charged from the capacitor C111 or the capacitor C112, the nodes N11 and N12 are rapidly replenished with electric charge even when currents rapidly flow from the nodes N11 and N12 to the switched-capacitor circuit 22. Thus, potential variations at the nodes N11 and N12 can be suppressed.

As a result of operating in the above-described manner, the switched-capacitor circuit 21 is configured to maintain substantially equal voltages across each of the capacitors C110 and C120. To be specific, the voltages V1 and V2 satisfying (V1−V2):(V2−VG)=1:1 are maintained at the two nodes labeled V1 and V2.

It is note that (V1−V2):(V2−VG) is not limited to 1:1 and may be designed to have any ratio (for example, 2:1, 3:1, 3:2, 1:2, or 2:3) according to alternative exemplary aspects.

### [1.3.2 Circuit Configuration of Switched-Capacitor Circuit 22]

Next, the circuit configuration of the switched-capacitor circuit 22 will be described with reference to FIG. 4. The switched-capacitor circuit 22 has a differential circuit configuration. To be specific, the switched-capacitor circuit 22 includes capacitors C210 to C212 and C220, switches S211 to S214 and S221 to S224, input terminals 221 and 222, and output terminals 223 to 225. Energy and electric charge are input from the switched-capacitor circuit 21 to nodes N21 and N23 via the input terminals 221 and 222 and withdrawn from nodes N21 to N23 to the supply modulator 30 via the output terminals 223 to 225.

The input terminal 221 is an example of a second input terminal and is a terminal for receiving an output voltage (V1) from the switched-capacitor circuit 21. The input terminal 221 is connected to the switched-capacitor circuit 21 outside the switched-capacitor circuit 22 and is connected to the node N21 inside the switched-capacitor circuit 22.

The input terminal 222 is an example of a third input terminal and is a terminal for receiving an input voltage (V2) from the switched-capacitor circuit 21. The input terminal 222 is connected to the switched-capacitor circuit 21 outside the switched-capacitor circuit 22 and is connected to the node N23 inside the switched-capacitor circuit 22.

The output terminal 223 is a terminal for supplying an output voltage (V1) to the supply modulator 30. The output terminal 223 is connected to the supply modulator 30 outside the switched-capacitor circuit 22 and is connected to the node N21 inside the switched-capacitor circuit 22. The output terminal 223 may be omitted from the switched-capacitor circuit 22 and instead integrated with the input terminal 221 according to an exemplary aspect.

The output terminal 224 is a terminal for supplying an output voltage (V2) to the supply modulator 30. The output terminal 224 is connected to the supply modulator 30 outside the switched-capacitor circuit 22 and is connected to the node N23 inside the switched-capacitor circuit 22. The output terminal 224 may be omitted from the switched-capacitor circuit 22 and instead integrated with the input terminal 222 according to an exemplary aspect.

The output terminal 225 is an example of a third output terminal and is a terminal for supplying an output voltage (V3) to the supply modulator 30. The output terminal 225 is connected to the supply modulator 30 outside the switched-capacitor circuit 22 and is connected to the node N22 inside the switched-capacitor circuit 22.

The output voltage (V3) is an example of a third output voltage and is generated from the output voltages (V1 and V2). In the present embodiment, the output voltage (V3) is lower than the output voltage (V1) and higher than the output voltage (V2).

The capacitors C211 and C212 are flying capacitors and are used to raise and/or lower the output voltages (V1 and V2) supplied from the switched-capacitor circuit 21. To be more specific, the capacitors C211 and C212 cause electric charge to move between the capacitors C211 and C212 and the nodes N21 to N23 so that the voltages V1 to V3 satisfying (V1−V3):(V3−V2)=1:1 and V1>V3>V2 are maintained at the three nodes N21 to N23.

One of the two electrodes of the capacitor C211 is connected to one end of the switch S211 and one end of the switch S212. The other of the two electrodes of the capacitor C211 is connected to one end of the switch S221 and one end of the switch S222.

One of the two electrodes of the capacitor C212 is connected to one end of the switch S213 and one end of the switch S214. The other of the two electrodes of the capacitor C212 is connected to one end of the switch S223 and one end of the switch S224.

In an exemplary aspect, the capacitors C211 and C212 can be charged and discharged in a complementary manner as a result of a first phase and a second phase being repeated.

To be specific, in the first phase, the switches S212, S213, S222, and S223 are closed, whereas the switches S211, S214, S221, and S224 are opened. Accordingly, the one of the two electrodes of the capacitor C211 is connected to the node N21, the other of the two electrodes of the capacitor C211 and the one of the two electrodes of the capacitor C212 are connected to the node N22, and the other of the two electrodes of the capacitor C212 is connected to the node N23.

On the other hand, in the second phase, the switches S212, S213, S222, and S223 are opened, whereas the switches S211, S214, S221, and S224 are closed. Accordingly, the one of the two electrodes of the capacitor C212 is connected to the node N21, the other of the two electrodes of the capacitor C212 and the one of the two electrodes of the capacitor C211 are connected to the node N22, and the other of the two electrodes of the capacitor C211 is connected to the node N23.

As a result of the first phase and the second phase being repeated, for example, when one of the capacitors C211 and C212 is charged through the node N21, the other of the capacitors C211 and C212 can be discharged to the capacitor C220. In short, the capacitors C211 and C212 can be charged and discharged in a complementary manner.

In the exemplary aspect, the capacitors C210 and C220 are configured as smoothing capacitors that hold and smooth the output voltages (V1, V3, and V2) at the nodes N21 to N23.

The capacitor C210 is connected between the nodes N21 and N22. To be specific, one of the two electrodes of the capacitor C210 is connected to the node N21. On the other hand, the other of the two electrodes of the capacitor C210 is connected to the node N22.

The capacitor C220 is connected between the nodes N22 and N23. To be specific, one of the two electrodes of the capacitor C220 is connected to the node N22. On the other hand, the other of the two electrodes of the capacitor C220 is connected to the node N23.

The switch S211 is connected between the capacitor C211 and the node N22. To be specific, the one end of the switch S211 is connected to the one of the two electrodes of the capacitor C211. On the other hand, the other end of the switch S211 is connected to the node N22.

The switch S212 is connected between the capacitor C211 and the node N21. To be specific, the one end of the switch S212 is connected to the one of the two electrodes of the capacitor C211. On the other hand, the other end of the switch S212 is connected to the node N21.

The switch S221 is connected between the capacitor C211 and the node N23. To be specific, the one end of the switch S221 is connected to the other of the two electrodes of the capacitor C211. On the other hand, the other end of the switch S221 is connected to the node N23.

The switch S222 is connected between the capacitor C211 and the node N22. To be specific, the one end of the switch S222 is connected to the other of the two electrodes of the capacitor C211. On the other hand, the other end of the switch S222 is connected to the node N22.

The switch S213 is connected between the capacitor C212 and the node N22. To be specific, the one end of the switch S213 is connected to the one of the two electrodes of the capacitor C212. On the other hand, the other end of the switch S213 is connected to the node N22. That is, the other end of the switch S213 is connected to the other end of the switch S211 and the other end of the switch S222.

The switch S214 is connected between the capacitor C212 and the node N21. To be specific, the one end of the switch S214 is connected to the one of the two electrodes of the capacitor C212. On the other hand, the other end of the switch S214 is connected to the node N21. That is, the other end of the switch S214 is connected to the other end of the switch S212.

The switch S223 is connected between the capacitor C212 and the node N23. To be specific, the one end of the switch S223 is connected to the other of the two electrodes of the capacitor C212. On the other hand, the other end of the switch S223 is connected to the node N23. That is, the other end of the switch S223 is connected to the other end of the switch S221.

The switch S224 is connected between the capacitor C212 and the node N22. To be specific, the one end of the switch S224 is connected to the other of the two electrodes of the capacitor C212. On the other hand, the other end of the switch S224 is connected to the node N22. That is, the other end of the switch S224 is connected to the other end of the switch S211, the other end of the switch S222, and the other end of the switch S213.

A first set of switches including the switches S212, S213, S222, and S223 and a second set of switches including the switches S211, S214, S221, and S224 are switched between open and close in a complementary manner based on a control signal from the digital control circuit 60. To be specific, in the first phase, the switches in the first set are closed whereas the switches in the second set are opened. On the other hand, in the second phase, the switches in the first set are opened whereas the switches in the second set are closed.

For example, in one of the first phase and the second phase, charging from the capacitor C211 to the capacitors C210 and C220 is performed, and in the other of the first phase and the second phase, charging from the capacitor C212 to the capacitors C210 and C220 is performed. In other words, because the capacitors C210 and C220 are constantly charged from the capacitor C211 or the capacitor C212, the nodes N21 to N23 are rapidly replenished with electric charge even when currents rapidly flow from the nodes N21 to N23 to the supply modulator 30. Thus, potential variations at the nodes N21 to N23 can be suppressed.

As a result of operating in the above-described manner, the switched-capacitor circuit 22 is configured to maintain substantially equal voltages across each of the capacitors C210 and C220. To be specific, the voltages V1 to V3 (voltages with respect to a ground potential) satisfying (V1−V3):(V3−V2)=1:1 are maintained at the three nodes labeled V1 to V3.

It is noted that (V1−V3):(V3−V2) is not limited to 1:1 and may be designed to have any ratio (for example, 2:1, 3:1, 3:2, 1:2, or 2:3) according to alternative exemplary aspects.

### [1.3.3 Circuit Configuration of Supply Modulator 30]

Next, the circuit configuration of the supply modulator 30 will be described with reference to FIG. 4. The supply modulator 30 includes input terminals 301 to 303, switches S51 to S53, and an output terminal 306.

The input terminals 301 to 303 are an example of a fourth input terminal, an example of a fifth input terminal, and an example of a sixth input terminal, respectively, and are terminals for receiving the output voltages (V1 to V3) generated by the switched-capacitor circuits 21 and 22. The input terminals 301 to 303 are respectively connected to the output terminals 223 to 225 of the switched-capacitor circuit 22 outside the supply modulator 30 and are respectively connected to the switches S51 to S53 inside the supply modulator 30. That is, the input terminal 301 is connected to the output terminal 213 of the switched-capacitor circuit 21 via the output terminal 223 and the input terminal 221 of the switched-capacitor circuit 22. The input terminal 302 is connected to the output terminal 214 of the switched-capacitor circuit 21 via the output terminal 224 and the input terminal 222 of the switched-capacitor circuit 22.

The output terminal 306 is an example of a fourth output terminal and is a terminal for selectively supplying at least one of a plurality of discrete voltages to the PA 2. The output terminal 306 is connected to the PA 2 outside the supply modulator 30 and is connected to the switches S51 to S53 inside the supply modulator 30.

The switch S51 is connected between the input terminal 301 and the output terminal 306. In this connection configuration, open/close switching of the switch S51 by a control signal from the digital control circuit 60 enables switching between connection and disconnection between the input terminal 301 and the output terminal 306.

The switch S52 is connected between the input terminal 302 and the output terminal 306. In this connection configuration, open/close switching of the switch S52 by a control signal from the digital control circuit 60 enables switching between connection and disconnection between the input terminal 302 and the output terminal 306.

The switch S53 is connected between the input terminal 303 and the output terminal 306. In this connection configuration, open/close switching of the switch S53 by a control signal from the digital control circuit 60 enables switching between connection and disconnection between the input terminal 303 and the output terminal 306.

In the present embodiment, these switches S51 to S53 are controlled so as to be exclusively turned ON. In other words, control is performed such that only any one of the switches S51 to S53 is closed and all the other switches are opened. Accordingly, the supply modulator 30 is configured to supply one voltage selected from among the plurality of discrete voltages (V1 to V3) to the PA 2.

The configuration of the supply modulator 30 illustrated in FIG. 4 is illustrative and is not restrictive. In particular, the switches S51 to S53 may have any configuration and may be controlled in any manner as long as at least one of the three input terminals 301 to 303 can be selectively connected to the output terminal 306. For example, two of the switches S51 to S53 may be closed and the other one of the switches S51 to S53 may be opened.

### [1.3.4 Circuit Configuration of Digital Control Circuit 60]

Next, the circuit configuration of the digital control circuit 60 will be described with reference to FIG. 4. The digital control circuit 60 includes a first controller 61, a second controller 62, and control terminals 601 to 604.

The first controller 61 is configured to process serial data signals supplied from the RFIC 5 via the control terminals 601 and 602 and generate a control signal for controlling the switched-capacitor circuits 21 and 22. The serial data signals may be, for example, source-synchronous digital control signals. Open/close of the switches S111 to S114 and S121 to S124 included in the switched-capacitor circuit 21 and the switches S211 to S214 and S221 to S224 included in the switched-capacitor circuit 22 is controlled by a control signal from the first controller 61.

Alternatively, clock-embedded digital control signals may be used as serial data signals. The first controller 61 may generate a control signal for controlling the supply modulator 30.

Although one set of a clock signal and a data signal is shared between the switched-capacitor circuits 21 and 22 in the present embodiment, it is noted that the exemplary aspects of the present disclosure are not limited thereto. For example, sets of a clock signal and a data signal may be individually used for the switched-capacitor circuits 21 and 22 in an alternative aspect.

The second controller 62 processes parallel data signals supplied from the RFIC 5 via the control terminals 603 and 604 and generates a control signal for controlling the supply modulator 30. The parallel data signals may be, for example, digitally controlled level (DCL) signals (DCL1 and DCL2). The DCL signals (DCL1 and DCL2) are generated, by the RFIC 5, based on an envelope signal of an RF signal. Open/close of the switches S51 to S53 included in the supply modulator 30 is controlled by a control signal from the second controller 62.

The DCL signals (DCL1 and DCL2) are each a 1-bit signal. The voltages V1 to V3 are each represented by a combination of two 1-bit signals. For example, V1, V2, and V3 are represented by “00”, “01”, and “10”, respectively. A gray code may be used to express a voltage level.

Although two DCL signals are used to control the supply modulator 30 in the present embodiment, the number of DCL signals is not limited thereto. For example, one or any number of three or more DCL signals may be used in accordance with the number of voltage levels selectable by each supply modulator 30. The parallel data signals used to control the supply modulator 30 are not limited to DCL signals.

### [1.4 Voltage Supply Method]

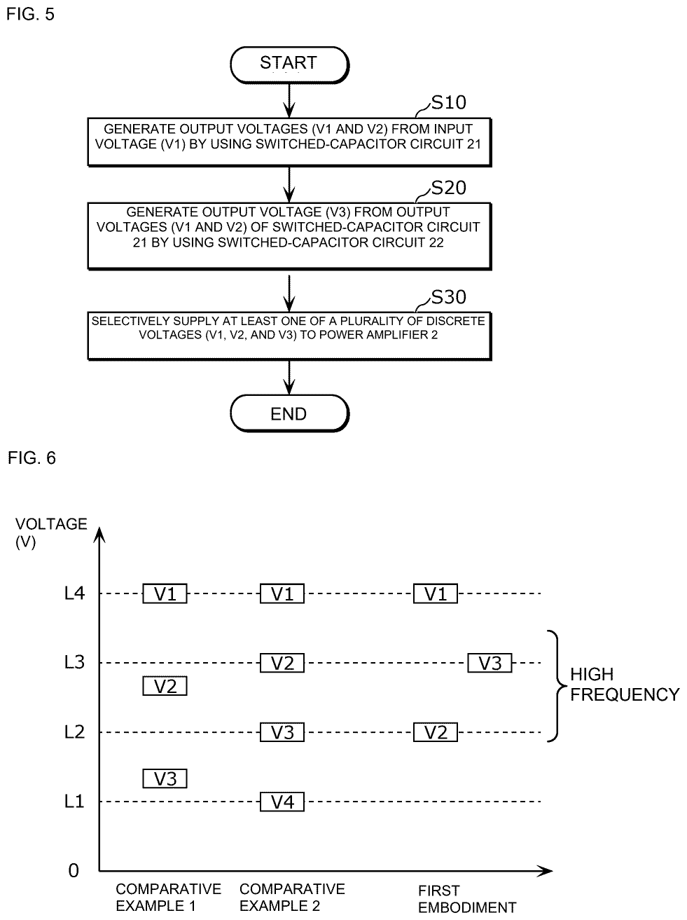

Next, a voltage supply method according to the present embodiment will be described with reference to FIG. 5. FIG. 5 is a flowchart illustrating the voltage supply method according to the present embodiment.

First, output voltages (V1 and V2) are generated from an input voltage (V1) by using the switched-capacitor circuit 21 (S10). Subsequently, output voltages (V1 to V3) are generated from the output voltages (V1 and V2) by using the switched-capacitor circuit 22 (S20). At this time, V1>V3>V2 is satisfied.

Finally, at least one of the plurality of discrete voltages (V1 to V3) is selectively supplied to the PA 2 by using the supply modulator 30 (S30). That is, at least one voltage is selected from among the plurality of discrete voltages (V1 to V3), and the selected at least one voltage is supplied to the PA 2. Such a voltage selection is performed based on an envelope signal, and thereby the D-ET mode is applied to the PA 2.

### [1.5 a Plurality of Discrete Voltages]

A plurality of discrete voltages that can be supplied by the tracker circuit 1 according to the present embodiment will be described with reference to FIG. 6. FIG. 6 is a diagram illustrating a plurality of discrete voltages that can be supplied in the present embodiment and comparative examples 1 and 2.

In comparative example 1, three discrete voltages are generated by using a ladder switched-capacitor circuit. In this case, the three discrete voltages (V1 to V3) are arranged at uniform level intervals between level L4 and a ground level. Only one voltage (V2) among the three discrete voltages (V1 to V3) is included in the range of voltages from L2 to L3.5 appropriate for increasing power-added efficiency in the power that occurs with a higher frequency near the average power of an RF signal (hereinafter referred to as a “high-frequency range”).

In comparative example 2, four discrete voltages are generated by using a ladder switched-capacitor circuit. In this case, the four discrete voltages (V1 to V4) are arranged at uniform level intervals between level L4 and the ground level, and two voltages (V2 and V3) among the four discrete voltages (V1 to V4) are included in the high-frequency range in FIG. 6.

In contrast to this, in the present embodiment, three discrete voltages are generated by using the ladder switched-capacitor circuit 21 and the differential switched-capacitor circuit 22. In this case, the three discrete voltages (V1 to V3) are arranged at non-uniform level intervals between level L4 and the ground level, and two voltages (V2 and V3) among the three discrete voltages (V1 to V3) are included in the high-frequency range in FIG. 6.

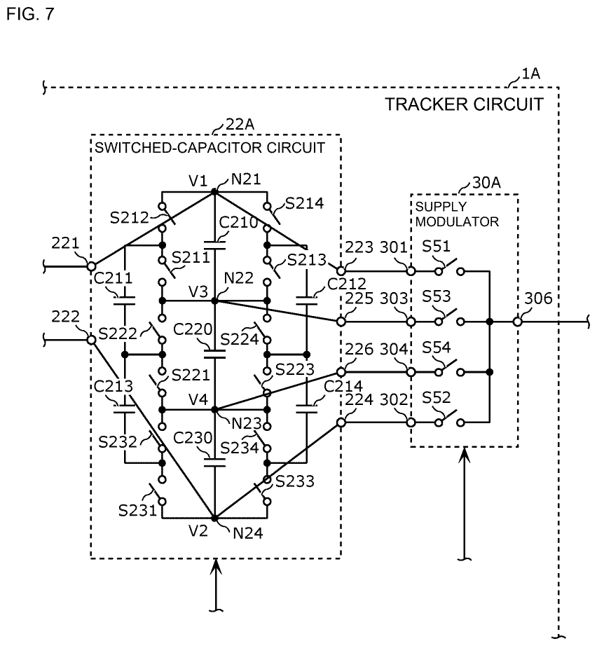

A larger number of discrete voltages included in the high-frequency range enables a voltage to be supplied more appropriately for the power of high occurrence frequency, which is effective to increase the power-added efficiency of the PA 2. It is noted that a voltage for maximum power (level L4 in FIG. 7) suppresses a decrease in linearity. On the other hand, a voltage lower than the high-frequency range is not so effective to increase the power-added efficiency of the PA 2 and leads to a decrease in the power efficiency of the tracker circuit 1.

In the present embodiment, the number of voltages included in the high-frequency range can be increased and the power-added efficiency of the PA 2 can be increased as compared with comparative example 1. In the present embodiment, the total number of the plurality of discrete voltages is reduced and thus the power efficiency of the tracker circuit 1 is improved and increased as compared with comparative example 2.

That is, in the present embodiment, the number of voltages included in the high-frequency range relative to the total number of the plurality of discrete voltages can be increased, and the power efficiency of the entire system is increased while an increase in the size of the tracker circuit 1 is suppressed.

### [1.6 Technical Effects]

As described above, the tracker circuit 1 according to the present embodiment includes the switched-capacitor circuit 21 configured to generate, from the first input voltage (V1), the first output voltage (V1) and the second output voltage (V2) that is lower than the first output voltage (V1); the switched-capacitor circuit 22 configured to generate, from the first output voltage (V1) and the second output voltage (V2), the third output voltage (V3) that is lower than the first output voltage (V1) and higher than the second output voltage (V2); and the supply modulator 30 configured to selectively output, to the PA 2, at least one of a plurality of discrete voltages including the first output voltage (V1), the second output voltage (V2), and the third output voltage (V3).

From another point of view, the tracker circuit 1 according to the present embodiment includes the switched-capacitor circuit 21 including the input terminal 211 that receives the first input voltage (V1), and the output terminals 213 and 214 that respectively output the first output voltage (V1) and the second output voltage (V2) that are generated from the first input voltage (V1), the second output voltage (V2) being lower than the first output voltage (V1); the switched-capacitor circuit 22 including the input terminals 221 and 222 respectively connected to the output terminals 213 and 214, and the output terminal 225 that outputs the third output voltage (V3) generated from the first output voltage (V1) and the second output voltage (V2), the third output voltage (V3) being lower than the first output voltage (V1) and higher than the second output voltage (V2); and the supply modulator 30 including the input terminals 301 to 303 respectively connected to the output terminals 213, 214, and 225, and the output terminal 306 connected to the PA 2.

Accordingly, the switched-capacitor circuit 21 generates the first output voltage (V1) and the second output voltage (V2), and furthermore the switched-capacitor circuit 22 generates the third output voltage (V3) between the first output voltage (V1) and the second output voltage (V2). Thus, the three discrete voltages (V1 to V3) can be generated at non-uniform level intervals. Thus, many discrete voltages can be generated in the range of voltages appropriate for the power that occurs with a higher frequency near the average power of an RF signal (a high-frequency range). As a result, in the D-ET mode, the voltage can be finely regulated for the power that occurs with a higher frequency, and the power-added efficiency of the PA 2 can be improved. On the contrary, voltages appropriate for the power that occurs with a lower frequency can be reduced. Thus, the total number of the plurality of discrete voltages is reduced, and the power efficiency of the tracker circuit 1 is increased.

For example, in the tracker circuit 1 according to the present embodiment, the switched-capacitor circuit 22 may be configured to generate, based on a difference between the first output voltage (V1) and the second output voltage (V2), the third output voltage (V3).

Accordingly, the switched-capacitor circuit 22 is configured to effectively generate the third output voltage (V3) between the first output voltage (V1) and the second output voltage (V2).

The communication device 7 according to the present embodiment includes the tracker circuit 1, the RFIC 5 configured to process an RF signal, and the RF circuit 4 including the PA 2 and configured to transmit the RF signal between the RFIC 5 and the antenna 6.

Accordingly, an effect similar to that of the tracker circuit 1 can be implemented in the communication device 7, and power consumption is effectively reduced.

The voltage supply method according to the present embodiment includes generating the first output voltage (V1) and the second output voltage (V2) from an input voltage by using the switched-capacitor circuit 21 (S10); generating the third output voltage (V3) from the first output voltage (V1) and the second output voltage (V2) by using the switched-capacitor circuit 22, the third output voltage (V3) being lower than the first output voltage (V1) and higher than the second output voltage (V2) (S20); and selectively supplying, to the PA 2, at least one of a plurality of discrete voltages including the first output voltage (V1), the second output voltage (V2), and the third output voltage (V3) (S30).

Accordingly, the switched-capacitor circuit 21 generates the first output voltage (V1) and the second output voltage (V2), and furthermore the switched-capacitor circuit 22 generates the third output voltage (V3) between the first output voltage (V1) and the second output voltage (V2). Thus, the three discrete voltages (V1 to V3) can be generated at non-uniform level intervals. Thus, many discrete voltages can be generated in the range of voltages appropriate for the power that occurs with a higher frequency near the average power of an RF signal (a high-frequency range). As a result, in the D-ET mode, the voltage can be finely regulated for the power that occurs with a higher frequency, and the power-added efficiency of the PA 2 can be improved. On the contrary, voltages appropriate for the power that occurs with a lower frequency can be reduced. Thus, the total number of the plurality of discrete voltages is reduced, and thus the power efficiency of the tracker circuit 1 is increased.

### Second Exemplary Embodiment

Hereinafter, a second exemplary embodiment will be described. The present embodiment is different from the first embodiment mainly in that the number of voltages generated by the switched-capacitor circuit in the second stage is larger than in the first embodiment. Hereinafter, the present embodiment will be described with a focus on differences from the first embodiment with reference to the drawings.

The communication device 7 according to the present embodiment is similar to the communication device 7 according to the first embodiment except that a tracker circuit 1A is included instead of the tracker circuit 1, and thus the illustration and description thereof is omitted.

### [2.1 Circuit Configuration of Tracker Circuit 1A]

The circuit configuration of the tracker circuit 1A will be described with reference to FIG. 7. FIG. 7 is a partial circuit configuration diagram of the tracker circuit 1A according to the present embodiment.

FIG. 7 illustrates an exemplary circuit configuration. The tracker circuit 1A can be implemented by using any of a wide variety of circuit implementations and circuit techniques. Thus, it should be appreciated that the description of the tracker circuit 1A provided below is not to be construed in a limiting manner.

The tracker circuit 1A is similar to the tracker circuit 1 according to the first embodiment except that a switched-capacitor circuit 22A and a supply modulator 30A are included instead of the switched-capacitor circuit 22 and the supply modulator 30. Thus, the circuit configurations of the switched-capacitor circuit 22A and the supply modulator 30A will be described below with reference to FIG. 7.

### [2.1.1 Circuit Configuration of Switched-Capacitor Circuit 22A]

The switched-capacitor circuit 22A is an example of a second switched-capacitor circuit and has a differential circuit configuration. To be specific, the switched-capacitor circuit 22A includes capacitors C210 to C214, C220, and C230, switches S211 to S214, S221 to S224, and S231 to S234, input terminals 221 and 222, and output terminals 223 to 226. Energy and electric charge are input from the switched-capacitor circuit 21 to nodes N21 and N24 via the input terminals 221 and 222 and withdrawn from nodes N21 to N24 to the supply modulator 30A via the output terminals 223 to 226.

The output terminal 226 is an example of a fifth output terminal and is a terminal for supplying an output voltage (V4) to the supply modulator 30A. The output terminal 226 is connected to the supply modulator 30A outside the switched-capacitor circuit 22A and is connected to the node N23 inside the switched-capacitor circuit 22A.

The output voltage (V4) is an example of a fourth output voltage and is generated from the output voltages (V1 and V2). In the present embodiment, the output voltage (V4) is lower than the output voltage (V3) and higher than the output voltage (V2).

The capacitors C213 and C214 are flying capacitors and are used to raise and/or lower the output voltages (V1 and V2) supplied from the switched-capacitor circuit 21. To be more specific, the capacitors C213 and C214 cause electric charge to move between the capacitors C213 and C214 and the nodes N22 to N24 so that the voltages V2 to V4 satisfying (V3−V4):(V4−V2)=1:1 and V3>V4>V2 are maintained at the three nodes N22 to N24.

One of the two electrodes of the capacitor C213 is connected to one end of the switch S221 and one end of the switch S222. The other of the two electrodes of the capacitor C213 is connected to one end of the switch S231 and one end of the switch S232.

One of the two electrodes of the capacitor C214 is connected to one end of the switch S223 and one end of the switch S224. The other of the two electrodes of the capacitor C214 is connected to one end of the switch S233 and one end of the switch S234.

The capacitor C230 is configured as a smoothing capacitor that holds and smooths the output voltage (V4) at the node N23. The capacitor C230 is connected between the nodes N23 and N24. To be specific, one of the two electrodes of the capacitor C230 is connected to the node N23. On the other hand, the other of the two electrodes of the capacitor C230 is connected to the node N24.

The switch S231 is connected between the capacitor C213 and the node N24. To be specific, the one end of the switch S231 is connected to the other of the two electrodes of the capacitor C213. On the other hand, the other end of the switch S231 is connected to the node N24.

The switch S232 is connected between the capacitor C213 and the node N23. To be specific, the one end of the switch S232 is connected to the other of the two electrodes of the capacitor C213. On the other hand, the other end of the switch S232 is connected to the node N23.

The switch S233 is connected between the capacitor C214 and the node N24. To be specific, the one end of the switch S233 is connected to the other of the two electrodes of the capacitor C214. On the other hand, the other end of the switch S233 is connected to the node N24.

The switch S234 is connected between the capacitor C214 and the node N23. To be specific, the one end of the switch S234 is connected to the other of the two electrodes of the capacitor C214. On the other hand, the other end of the switch S234 is connected to the node N23.

A first set of switches including the switches S212, S213, S222, S223, S232, and S233 and a second set of switches including the switches S211, S214, S221, S224, S231, and S234 are switched between open and close in a complementary manner based on a control signal from the digital control circuit 60. To be specific, in a first phase, the switches in the first set are closed whereas the switches in the second set are opened. On the other hand, in a second phase, the switches in the first set are opened whereas the switches in the second set are closed.

As a result of operating in the above-described manner, the switched-capacitor circuit 22A is configured to maintain substantially equal voltages across each of the capacitors C210 to C230. To be specific, the voltages V1 to V4 (voltages with respect to a ground potential) satisfying (V1−V3):(V3−V4):(V4−V2)=1:1:1 are maintained at the four nodes labeled V1 to V4.

It is noted that (V1−V3):(V3−V4):(V4−V2) is not limited to 1:1:1 and may be designed to have any ratio (for example, 1:2:4 or 4:2:1) according to alternative exemplary aspects.

### [2.1.2 Circuit Configuration of Supply Modulator 30A]

Next, the circuit configuration of the supply modulator 30A will be described with reference to FIG. 7. The supply modulator 30A includes input terminals 301 to 304, switches S51 to S54, and an output terminal 306.

The input terminal 304 is an example of a seventh input terminal and is a terminal for receiving the output voltage (V4) generated by the switched-capacitor circuit 22A. The input terminal 304 is connected to the output terminal 226 of the switched-capacitor circuit 22A outside the supply modulator 30A and is connected to the switch S54 inside the supply modulator 30A.

The switch S54 is connected between the input terminal 304 and the output terminal 306. In this connection configuration, open/close switching of the switch S54 by a control signal from the digital control circuit 60 enables switching between connection and disconnection between the input terminal 304 and the output terminal 306.

In the present embodiment, the switches S51 to S54 are controlled so as to be exclusively turned ON. In other words, control is performed such that only any one of the switches S51 to S54 is closed and all the other switches are opened. Accordingly, the supply modulator 30A is configured to supply one voltage selected from among the plurality of discrete voltages (V1 to V4) to the PA 2.

The configuration of the supply modulator 30A illustrated in FIG. 7 is illustrative and is not restrictive. In particular, the switches S51 to S54 may have any configuration and may be controlled in any manner as long as at least one of the four input terminals 301 to 304 can be selectively connected to the output terminal 306. For example, two of the switches S51 to S54 may be closed, and the other two of the switches S51 to S54 may be opened.

### [2.2 a Plurality of Discrete Voltages]

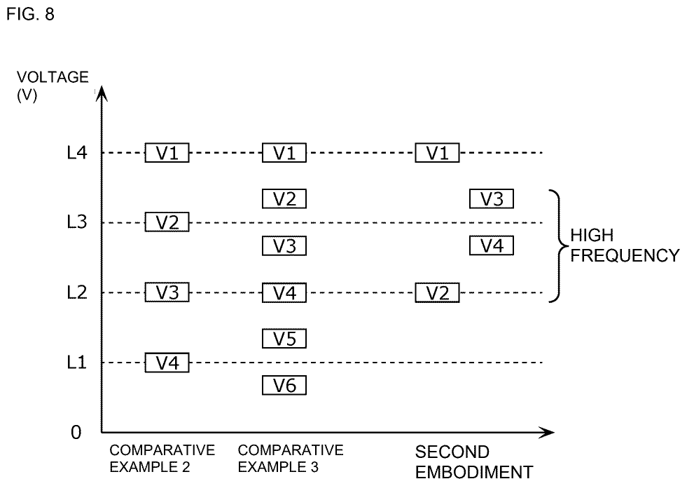

A plurality of discrete voltages that can be supplied by the tracker circuit 1A according to the present embodiment will be described with reference to FIG. 8. FIG. 8 is a diagram illustrating a plurality of discrete voltages that can be supplied in the present embodiment and comparative examples 2 and 3.

In comparative example 2, four discrete voltages are generated by using a ladder switched-capacitor circuit. In this case, the four discrete voltages (V1 to V4) are arranged at uniform level intervals between level L4 and the ground level, and two voltages (V2 and V3) among the four discrete voltages (V1 to V4) are included in the high-frequency range in FIG. 8.

In comparative example 3, six discrete voltages are generated by using a ladder switched-capacitor circuit. In this case, the six discrete voltages (V1 to V6) are arranged at uniform level intervals between level L4 and the ground level, and three voltages (V2 to V4) among the six discrete voltages (V1 to V6) are included in the high-frequency range in FIG. 8.

In contrast to this, in the present embodiment, four discrete voltages are generated by using the ladder switched-capacitor circuit 21 and the differential switched-capacitor circuit 22A. In this case, the four discrete voltages (V1 to V4) are arranged at non-uniform level intervals between level L4 and the ground level, and three voltages (V2 to V4) among the four discrete voltages (V1 to V4) are included in the high-frequency range in FIG. 8.

Accordingly, in the present embodiment, the number of voltages included in the high-frequency range can be increased and the power-added efficiency can be increased as compared with comparative example 2. In the present embodiment, the total number of the plurality of discrete voltages is and thus the power efficiency of the tracker circuit 1A is increased as compared with comparative example 3.

That is, in the present embodiment, the number of voltages included in the high-frequency range relative to the total number of the plurality of discrete voltages can be increased, and the power-added efficiency can be increased while an increase in the size of the tracker circuit 1A is suppressed.

### [2.3 Technical Effects]

As described above, the tracker circuit 1A according to the present embodiment includes the switched-capacitor circuit 21 configured to generate, from the first input voltage (V1), the first output voltage (V1) and the second output voltage (V2) that is lower than the first output voltage (V1); the switched-capacitor circuit 22A configured to generate, from the first output voltage (V1) and the second output voltage (V2), the third output voltage (V3) that is lower than the first output voltage (V1) and higher than the second output voltage (V2) and the fourth output voltage (V4) that is lower than the third output voltage (V3) and higher than the second output voltage (V2); and the supply modulator 30A configured to selectively output, to the PA 2, at least one of a plurality of discrete voltages including the first output voltage (V1), the second output voltage (V2), the third output voltage (V3), and the fourth output voltage (V4).

From another point of view, the tracker circuit 1A according to the present embodiment includes the switched-capacitor circuit 21 including the input terminal 211 that receives the first input voltage (V1), and the output terminals 213 and 214 that respectively output the first output voltage (V1) and the second output voltage (V2) that are generated from the first input voltage (V1), the second output voltage (V2) being lower than the first output voltage (V1); the switched-capacitor circuit 22A including the input terminals 221 and 222 respectively connected to the output terminals 213 and 214, and the output terminals 225 and 226 that respectively output the third output voltage (V3) and the fourth output voltage (V4) that are generated from the first output voltage (V1) and the second output voltage (V2), the third output voltage (V3) being lower than the first output voltage (V1) and higher than the second output voltage (V2), the fourth output voltage (V4) being higher than the second output voltage (V2) and lower than the third output voltage (V3); and the supply modulator 30A including the input terminals 301 to 304 respectively connected to the output terminals 213, 214, 225, and 226, and the output terminal 306 connected to the PA 2.

Accordingly, the switched-capacitor circuit 21 generates the first output voltage (V1) and the second output voltage (V2), and furthermore the switched-capacitor circuit 22A generates the third output voltage (V3) and the fourth output voltage (V4) between the first output voltage (V1) and the second output voltage (V2). Thus, the four discrete voltages (V1 to V4) can be generated at non-uniform level intervals. Thus, many discrete voltages can be generated in the range of voltages appropriate for the power that occurs with a higher frequency near the average power of an RF signal (e.g., a high-frequency range). As a result, in the D-ET mode, the voltage can be finely regulated for the power that occurs with a higher frequency, and the power-added efficiency of the PA 2 can be improved. On the contrary, voltages appropriate for the power that occurs with a lower frequency can be reduced. Thus, the total number of the plurality of discrete voltages is reduced, and thus the power efficiency of the tracker circuit 1A is increased.

For example, in the tracker circuit 1A according to the present embodiment, the switched-capacitor circuit 22A may be configured to generate, based on a difference between the first output voltage (V1) and the second output voltage (V2), the third output voltage (V3) and the fourth output voltage (V4).

Accordingly, the switched-capacitor circuit 22A is configured to effectively generate the third output voltage (V3) and the fourth output voltage (V4) between the first output voltage (V1) and the second output voltage (V2).

The communication device 7 according to the present embodiment includes the tracker circuit 1A, the RFIC 5 configured to process an RF signal, and the RF circuit 4 including the PA 2 and configured to transmit the RF signal between the RFIC 5 and the antenna 6.

Accordingly, an effect similar to that of the tracker circuit 1A can be implemented in the communication device 7, and power consumption can be effectively reduced.

### Third Exemplary Embodiment

Hereinafter, a third exemplary embodiment will be described. The present embodiment is different from the first and second embodiments mainly in that the number of voltages generated by the switched-capacitor circuit in the second stage is larger than in the first and second embodiments. Hereinafter, the present embodiment will be described with a focus on differences from the first and second embodiments with reference to the drawings.

The communication device 7 according to the present embodiment is similar to the communication device 7 according to the first embodiment except that a tracker circuit 1B is included instead of the tracker circuit 1, and thus the illustration and description thereof is omitted.

### [3.1 Circuit Configuration of Tracker Circuit 1B]

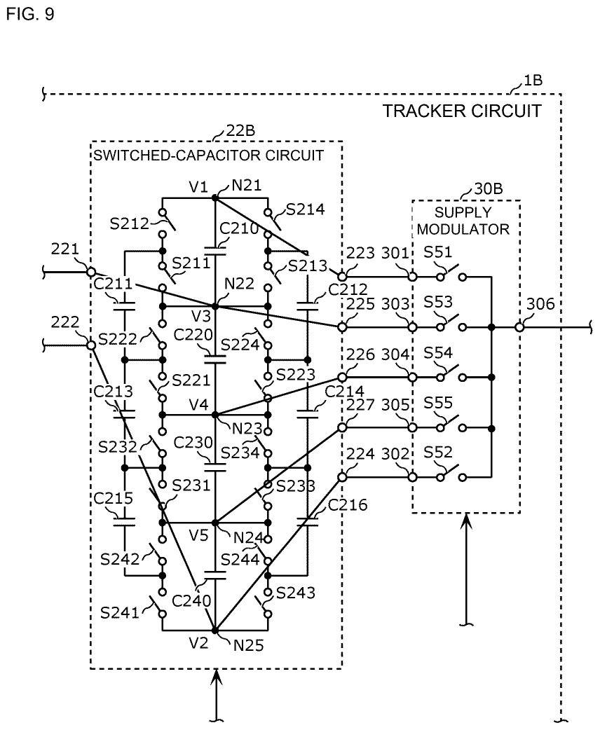

The circuit configuration of the tracker circuit 1B will be described with reference to FIG. 9. FIG. 9 is a partial circuit configuration diagram of the tracker circuit 1B according to the present embodiment.

FIG. 9 illustrates an exemplary circuit configuration. The tracker circuit 1B can be implemented by using any of a wide variety of circuit implementations and circuit techniques. Thus, it should be appreciated that the description of the tracker circuit 1B provided below is not to be construed in a limiting manner.

The tracker circuit 1B is similar to the tracker circuit 1 according to the first embodiment except that a switched-capacitor circuit 22B and a supply modulator 30B are included instead of the switched-capacitor circuit 22 and the supply modulator 30. Thus, the circuit configurations of the switched-capacitor circuit 22B and the supply modulator 30B will be described below with reference to FIG. 9.

### [3.1.1 Circuit Configuration of Switched-Capacitor Circuit 22B]

The switched-capacitor circuit 22B is an example of a second switched-capacitor circuit and has a differential circuit configuration. To be specific, the switched-capacitor circuit 22B includes capacitors C210 to C216, C220, C230, and C240, switches S211 to S214, S221 to S224, S231 to S234, and S241 to S244, input terminals 221 and 222, and output terminals 223 to 227. Energy and electric charge are input from the switched-capacitor circuit 21 to nodes N21 and N25 via the input terminals 221 and 222 and withdrawn from nodes N21 to N25 to the supply modulator 30B via the output terminals 223 to 227.

The output terminal 227 is an example of a sixth output terminal and is a terminal for supplying an output voltage (V5) to the supply modulator 30B. The output terminal 227 is connected to the supply modulator 30B outside the switched-capacitor circuit 22B and is connected to the node N24 inside the switched-capacitor circuit 22B.

The output voltage (V5) is an example of a fifth output voltage and is generated from the output voltages (V1 and V2). In the present embodiment, the output voltage (V5) is lower than the output voltage (V4) and higher than the output voltage (V2).

The capacitors C215 and C216 are flying capacitors and are used to raise and/or lower the output voltages (V1 and V2) supplied from the switched-capacitor circuit 21. To be more specific, the capacitors C215 and C216 cause electric charge to move between the capacitors C215 and C216 and the nodes N23 to N25 so that the voltages V2, V4, and V5 satisfying (V4−V5):(V5−V2)=1:1 and V4>V5>V2 are maintained at the three nodes N23 to N25.

One of the two electrodes of the capacitor C215 is connected to one end of the switch S231 and one end of the switch S232. The other of the two electrodes of the capacitor C215 is connected to one end of the switch S241 and one end of the switch S242.

One of the two electrodes of the capacitor C216 is connected to one end of the switch S233 and one end of the switch S234. The other of the two electrodes of the capacitor C216 is connected to one end of the switch S243 and one end of the switch S244.

The capacitor C240 is a configured as a smoothing capacitor that holds and smooths the output voltage (V5) at the node N24. The capacitor C240 is connected between the nodes N24 and N25. To be specific, one of the two electrodes of the capacitor C240 is connected to the node N24. On the other hand, the other of the two electrodes of the capacitor C240 is connected to the node N25.

The switch S241 is connected between the capacitor C215 and the node N25. To be specific, the one end of the switch S241 is connected to the other of the two electrodes of the capacitor C215. On the other hand, the other end of the switch S241 is connected to the node N25.

The switch S242 is connected between the capacitor C215 and the node N24. To be specific, the one end of the switch S242 is connected to the other of the two electrodes of the capacitor C215. On the other hand, the other end of the switch S242 is connected to the node N24.

The switch S243 is connected between the capacitor C216 and the node N25. To be specific, the one end of the switch S243 is connected to the other of the two electrodes of the capacitor C216. On the other hand, the other end of the switch S243 is connected to the node N25.

The switch S244 is connected between the capacitor C216 and the node N24. To be specific, the one end of the switch S244 is connected to the other of the two electrodes of the capacitor C216. On the other hand, the other end of the switch S244 is connected to the node N24.

A first set of switches including the switches S212, S213, S222, S223, S232, S233, S242, and S243 and a second set of switches including the switches S211, S214, S221, S224, S231, S234, S241, and S244 are switched between open and close in a complementary manner based on a control signal from the digital control circuit 60. To be specific, in a first phase, the switches in the first set are closed whereas the switches in the second set are opened. On the other hand, in a second phase, the switches in the first set are opened whereas the switches in the second set are closed.

As a result of operating in the above-described manner, the switched-capacitor circuit 22B is configured to maintain substantially equal voltages across each of the capacitors C210 to C240. To be specific, the voltages V1 to V5 (voltages with respect to a ground potential) satisfying (V1−V3):(V3−V4):(V4−V5):(V5−V2)=1:1:1:1 are maintained at the five nodes labeled V1 to V5.

It is noted that (V1−V3):(V3−V4):(V4−V5):(V5−V2) is not limited to 1:1:1:1 and may be designed to have any ratio (for example, 1:2:4:8 or 8:4:2:1) according to alternative aspects.

### [3.1.2 Circuit Configuration of Supply Modulator 30B]

Next, the circuit configuration of the supply modulator 30B will be described with reference to FIG. 9. The supply modulator 30B includes input terminals 301 to 305, switches S51 to S55, and an output terminal 306.

The input terminal 305 is an example of an eighth input terminal and is a terminal for receiving the output voltage (V5) generated by the switched-capacitor circuit 22B. The input terminal 305 is connected to the output terminal 227 of the switched-capacitor circuit 22B outside the supply modulator 30B and is connected to the switch S55 inside the supply modulator 30B.

The switch S55 is connected between the input terminal 305 and the output terminal 306. In this connection configuration, open/close switching of the switch S55 by a control signal from the digital control circuit 60 enables switching between connection and disconnection between the input terminal 305 and the output terminal 306.

In the present embodiment, the switches S51 to S55 are controlled so as to be exclusively turned ON. In other words, control is performed such that only any one of the switches S51 to S55 is closed and all the other switches are opened. Accordingly, the supply modulator 30B is configured to supply one voltage selected from among the plurality of discrete voltages (V1 to V5) to the PA 2.

The configuration of the supply modulator 30B illustrated in FIG. 9 is illustrative and is not restrictive. In particular, the switches S51 to S55 may have any configuration and may be controlled in any manner as long as at least one of the five input terminals 301 to 305 can be selectively connected to the output terminal 306. For example, two of the switches S51 to S55 may be closed, and the other three of the switches S51 to S55 may be opened.

### [3.2 a Plurality of Discrete Voltages]

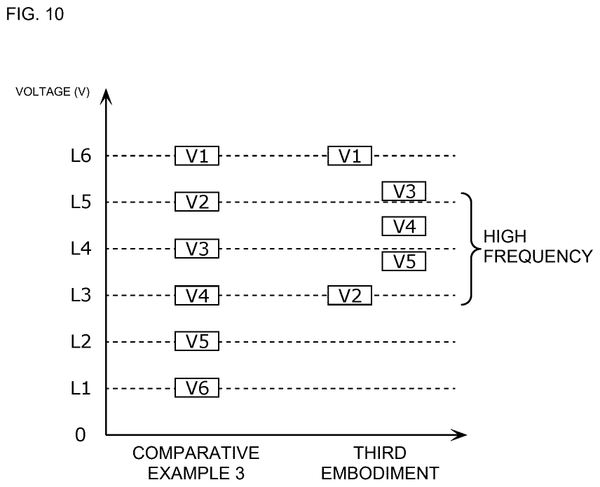

A plurality of discrete voltages that can be supplied by the tracker circuit 1B according to the present embodiment will be described with reference to FIG. 10. FIG. 10 is a diagram illustrating a plurality of discrete voltages that can be supplied in the present embodiment and comparative example 3.

In comparative example 3, six discrete voltages are generated by using a ladder switched-capacitor circuit. In this case, the six discrete voltages (V1 to V6) are arranged at uniform level intervals between level L6 and the ground level, and three voltages (V2 to V4) among the six discrete voltages (V1 to V6) are included in the high-frequency range in FIG. 10.

In contrast to this, in the present embodiment, five discrete voltages are generated by using the ladder switched-capacitor circuit 21 and the differential switched-capacitor circuit 22B. In this case, the five discrete voltages (V1 to V5) are arranged at non-uniform level intervals between level L6 and the ground level, and four voltages (V2 to V5) among the five discrete voltages (V1 to V5) are included in the high-frequency range in FIG. 10.

Accordingly, in the present embodiment, the number of voltages included in the high-frequency range can be increased and the power-added efficiency can be increased as compared with comparative example 3. In the present embodiment, the total number of the plurality of discrete voltages is reduced and thus the power efficiency of the tracker circuit 1B is increased as compared with comparative example 3.

That is, in the present embodiment, the number of voltages included in the high-frequency range relative to the total number of the plurality of discrete voltages can be increased, and the power-added efficiency can be increased while an increase in the size of the tracker circuit 1B is suppressed.

### [3.3 Technical Effects]

As described above, the tracker circuit 1B according to the present embodiment includes the switched-capacitor circuit 21 configured to generate, from the first input voltage (V1), the first output voltage (V1) and the second output voltage (V2) that is lower than the first output voltage (V1); the switched-capacitor circuit 22B configured to generate, from the first output voltage (V1) and the second output voltage (V2), the third output voltage (V3) that is lower than the first output voltage (V1) and higher than the second output voltage (V2), the fourth output voltage (V4) that is lower than the third output voltage (V3) and higher than the second output voltage (V2), and the fifth output voltage (V5) that is lower than the fourth output voltage (V4) and higher than the second output voltage (V2); and the supply modulator 30B configured to selectively output, to the PA 2, at least one of a plurality of discrete voltages including the first output voltage (V1), the second output voltage (V2), the third output voltage (V3), the fourth output voltage (V4), and the fifth output voltage (V5).

From another point of view, the tracker circuit 1B according to the present embodiment includes the switched-capacitor circuit 21 including the input terminal 211 that receives the first input voltage (V1), and the output terminals 213 and 214 that respectively output the first output voltage (V1) and the second output voltage (V2) that are generated from the first input voltage (V1), the second output voltage (V2) being lower than the first output voltage (V1); the switched-capacitor circuit 22B including the input terminals 221 and 222 respectively connected to the output terminals 213 and 214, and the output terminals 225, 226, and 227 that respectively output the third output voltage (V3), the fourth output voltage (V4), and the fifth output voltage (V5) that are generated from the first output voltage (V1) and the second output voltage (V2), the third output voltage (V3) being lower than the first output voltage (V1) and higher than the second output voltage (V2), the fourth output voltage (V4) being higher than the second output voltage (V2) and lower than the third output voltage (V3), the fifth output voltage (V5) being higher than the second output voltage (V2) and lower than the fourth output voltage (V4); and the supply modulator 30B including the input terminals 301 to 305 respectively connected to the output terminals 213, 214, 225, 226, and 227, and the output terminal 306 connected to the PA 2.

Accordingly, the switched-capacitor circuit 21 generates the first output voltage (V1) and the second output voltage (V2), and furthermore the switched-capacitor circuit 22B generates the third output voltage (V3), the fourth output voltage (V4), and the fifth output voltage (V5) between the first output voltage (V1) and the second output voltage (V2). Thus, the five discrete voltages (V1 to V5) can be generated at non-uniform level intervals. Thus, many discrete voltages can be generated in the range of voltages appropriate for the power that occurs with a higher frequency near the average power of an RF signal (a high-frequency range). As a result, in the D-ET mode, the voltage can be finely regulated for the power that occurs with a higher frequency, and the power-added efficiency of the PA 2 can be improved. On the contrary, voltages appropriate for the power that occurs with a lower frequency can be reduced. Thus, the total number of the plurality of discrete voltages is reduced, and thus the power efficiency of the tracker circuit 1B is increased.

For example, in the tracker circuit 1B according to the present embodiment, the switched-capacitor circuit 22B may be configured to generate, based on a difference between the first output voltage (V1) and the second output voltage (V2), the third output voltage (V3), the fourth output voltage (V4), and the fifth output voltage (V5).

Accordingly, the switched-capacitor circuit 22B is configured to effectively generate the third output voltage (V3), the fourth output voltage (V4), and the fifth output voltage (V5) between the first output voltage (V1) and the second output voltage (V2).

The communication device 7 according to the present embodiment includes the tracker circuit 1B, the RFIC 5 configured to process an RF signal, and the RF circuit 4 including the PA 2 and configured to transmit the RF signal between the RFIC 5 and the antenna 6.

Accordingly, an effect similar to that of the tracker circuit 1B can be implemented in the communication device 7, and power consumption can be effectively reduced.

### Fourth Exemplary Embodiment

Hereinafter, a fourth exemplary embodiment will be described. The present embodiment is different from the first embodiment mainly in that the number of voltages generated by the switched-capacitor circuit in the first stage is larger than in the first embodiment. Hereinafter, the present embodiment will be described with a focus on differences from the first embodiment with reference to the drawings.

The communication device 7 according to the present embodiment is similar to the communication device 7 according to the first embodiment except that a tracker circuit 1C is included instead of the tracker circuit 1, and thus the illustration and description thereof is omitted.

### [4.1 Circuit Configuration of Tracker Circuit 1C]

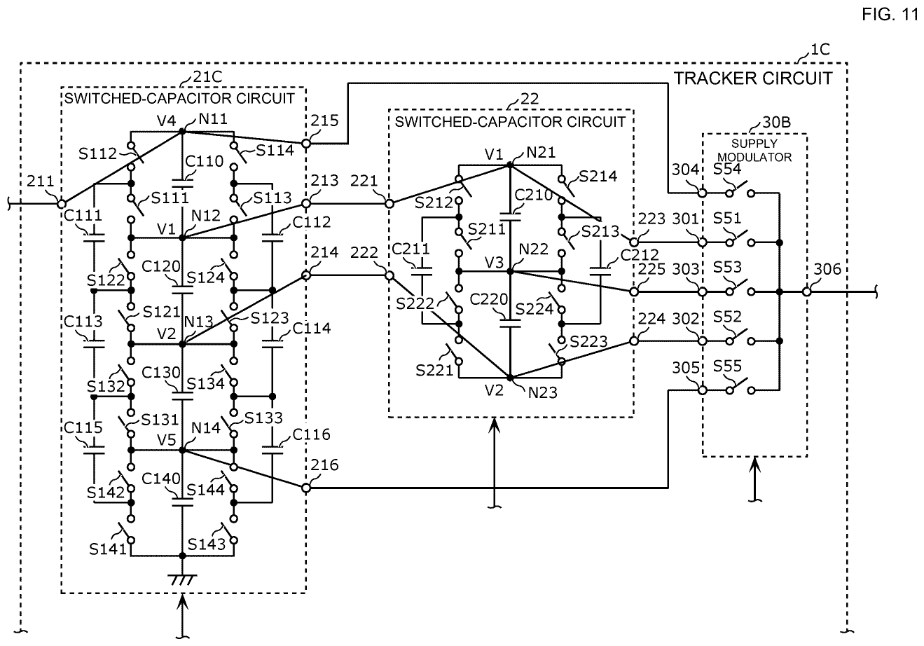

The circuit configuration of the tracker circuit 1C will be described with reference to FIG. 11. FIG. 11 is a partial circuit configuration diagram of the tracker circuit 1C according to the present embodiment.

FIG. 11 illustrates an exemplary circuit configuration. The tracker circuit 1C can be implemented by using any of a wide variety of circuit implementations and circuit techniques. Thus, it should be appreciated that the description of the tracker circuit 1C provided below is not to be construed in a limiting manner.

The tracker circuit 1C is similar to the tracker circuit 1 according to the first embodiment except that a switched-capacitor circuit 21C and a supply modulator 30B are included instead of the switched-capacitor circuit 21 and the supply modulator 30. Thus, the circuit configurations of the switched-capacitor circuit 21C and the supply modulator 30B will be described below with reference to FIG. 11.

### [4.1.1 Circuit Configuration of Switched-Capacitor Circuit 21C]

The switched-capacitor circuit 21C is an example of a first switched-capacitor circuit and has a ladder circuit configuration. To be specific, the switched-capacitor circuit 21C includes capacitors C110 to C116, C120, C130, and C140, switches S111 to S114, S121 to S124, S131 to S134, and S141 to S144, an input terminal 211, and output terminals 213 to 216. Energy and electric charge are input from the pre-regulator circuit 10 to a node N11 via the input terminal 211 and withdrawn from nodes N11 to N14 to the switched-capacitor circuit 22 and the supply modulator 30B via the output terminals 213 to 216.

The output terminal 215 is an example of a fifth output terminal and is a terminal for supplying an output voltage (V4) to the supply modulator 30B. The output terminal 215 is connected to the supply modulator 30B outside the switched-capacitor circuit 21C and is connected to the node N11 inside the switched-capacitor circuit 21C.

The output voltage (V4) is an example of a fourth output voltage and is generated from the input voltage (V1). In the present embodiment, the output voltage (V4) is higher than the output voltage (V1).

The output terminal 216 is an example of a sixth output terminal and is a terminal for supplying an output voltage (V5) to the supply modulator 30B. The output terminal 216 is connected to the supply modulator 30B outside the switched-capacitor circuit 21C and is connected to the node N14 inside the switched-capacitor circuit 21C.

The output voltage (V5) is an example of a fifth output voltage and is generated from the input voltage (V1). In the present embodiment, the output voltage (V5) is lower than the output voltage (V2).

The capacitors C111 and C116 are flying capacitors and are used to raise and/or lower the input voltage (V1) supplied from the pre-regulator circuit 10. To be more specific, the capacitors C111 to C116 cause electric charge to move from/to the capacitors C111 to C116 to/from the nodes N11 to N14 and ground so that the voltages V1, V2, V4, and V5 satisfying (V4−V1):(V1−V2):(V2−V5):(V5−VG)=1:1:1:1 and V4>V1>V2>V5>VG are maintained at the four nodes N11 to N14.

One of the two electrodes of the capacitor C113 is connected to one end of the switch S121 and one end of the switch S122. The other of the two electrodes of the capacitor C113 is connected to one end of the switch S131 and one end of the switch S132.

One of the two electrodes of the capacitor C114 is connected to one end of the switch S123 and one end of the switch S124. The other of the two electrodes of the capacitor C114 is connected to one end of the switch S133 and one end of the switch S134.

One of the two electrodes of the capacitor C115 is connected to the one end of the switch S131 and the one end of the switch S132. The other of the two electrodes of the capacitor C115 is connected to one end of the switch S141 and one end of the switch S142.

One of the two electrodes of the capacitor C116 is connected to the one end of the switch S133 and the one end of the switch S134. The other of the two electrodes of the capacitor C116 is connected to one end of the switch S143 and one end of the switch S144.

The capacitors C110 to C140 are configured as smoothing capacitors that hold and smooth the output voltages (V4, V1, V2, and V5) at the nodes N11 to N14. The capacitor C130 is connected between the nodes N13 and N14, and the capacitor C140 is connected between the node N14 and ground.

The switch S131 is connected between the capacitor C113 and the node N14 and is connected between the capacitor C115 and the node N14. To be specific, the one end of the switch S131 is connected to the other of the two electrodes of the capacitor C113 and is connected to the one of the two electrodes of the capacitor C115. On the other hand, the other end of the switch S131 is connected to the node N14.

The switch S132 is connected between the capacitor C113 and the node N13 and is connected between the capacitor C115 and the node N13. To be specific, the one end of the switch S132 is connected to the other of the two electrodes of the capacitor C113 and is connected to the one of the two electrodes of the capacitor C115. On the other hand, the other end of the switch S132 is connected to the node N13.

The switch S133 is connected between the capacitor C114 and the node N14 and is connected between the capacitor C116 and the node N14. To be specific, the one end of the switch S133 is connected to the other of the two electrodes of the capacitor C114 and is connected to the one of the two electrodes of the capacitor C116. On the other hand, the other end of the switch S133 is connected to the node N14.

The switch S134 is connected between the capacitor C114 and the node N13 and is connected between the capacitor C116 and the node N13. To be specific, the one end of the switch S134 is connected to the other of the two electrodes of the capacitor C114 and is connected to the one of the two electrodes of the capacitor C116. On the other hand, the other end of the switch S134 is connected to the node N13.

The switch S141 is connected between the capacitor C115 and ground. To be specific, the one end of the switch S141 is connected to the other of the two electrodes of the capacitor C115. On the other hand, the other end of the switch S141 is connected to ground.

The switch S142 is connected between the capacitor C115 and the node N14. To be specific, the one end of the switch S142 is connected to the other of the two electrodes of the capacitor C115. On the other hand, the other end of the switch S142 is connected to the node N14.

The switch S143 is connected between the capacitor C116 and ground. To be specific, the one end of the switch S143 is connected to the other of the two electrodes of the capacitor C116. On the other hand, the other end of the switch S143 is connected to ground.

The switch S144 is connected between the capacitor C116 and the node N14. To be specific, the one end of the switch S144 is connected to the other of the two electrodes of the capacitor C116. On the other hand, the other end of the switch S144 is connected to the node N14.

A first set of switches including the switches S112, S113, S122, S123, S132, S133, S142, and S143 and a second set of switches including the switches S111, S114, S121, S124, S131, S134, S141, and S144 are switched between open and close in a complementary manner based on a control signal from the digital control circuit 60. To be specific, in a first phase, the switches in the first set are closed whereas the switches in the second set are opened. On the other hand, in a second phase, the switches in the first set are opened whereas the switches in the second set are closed.

As a result of operating in the above-described manner, the switched-capacitor circuit 21C is configured to maintain substantially equal voltages across each of the capacitors C110 to C130. To be specific, the voltages V1, V2, V4, and V5 (voltages with respect to a ground potential) satisfying (V4−V1):(V1−V2):(V2−V5):(V5−VG)=1:1:1:1 are maintained at the four nodes labeled V1, V2, V4 and V5.

It is noted that (V4−V1):(V1−V2):(V2−V5):(V5−VG) is not limited to 1:1:1:1 and may be designed to have any ratio (for example, 1:2:4:8 or 8:4:2:1) according to alternative exemplary aspects.

### [4.1.2 Circuit Configuration of Supply Modulator 30B]

Next, the circuit configuration of the supply modulator 30B will be described with reference to FIG. 11. The supply modulator 30B includes input terminals 301 to 305, switches S51 to S55, and an output terminal 306.

The supply modulator 30B according to the present embodiment is similar to the supply modulator 30B according to the third embodiment except that the connections of the input terminals 304 and 305 outside the supply modulator 30B are different. Thus, the description of the input terminals 304 and 305 will be provided, and the description of the other part will be omitted.

The input terminal 304 is an example of a seventh input terminal and is a terminal for receiving the output voltage (V4) generated by the switched-capacitor circuit 21C. The input terminal 304 is connected to the output terminal 215 of the switched-capacitor circuit 21C outside the supply modulator 30B and is connected to the switch S54 inside the supply modulator 30B.

The input terminal 305 is an example of an eighth input terminal and is a terminal for receiving the output voltage (V5) generated by the switched-capacitor circuit 21C. The input terminal 305 is connected to the output terminal 216 of the switched-capacitor circuit 21C outside the supply modulator 30B and is connected to the switch S55 inside the supply modulator 30B.

### [4.2 a Plurality of Discrete Voltages]

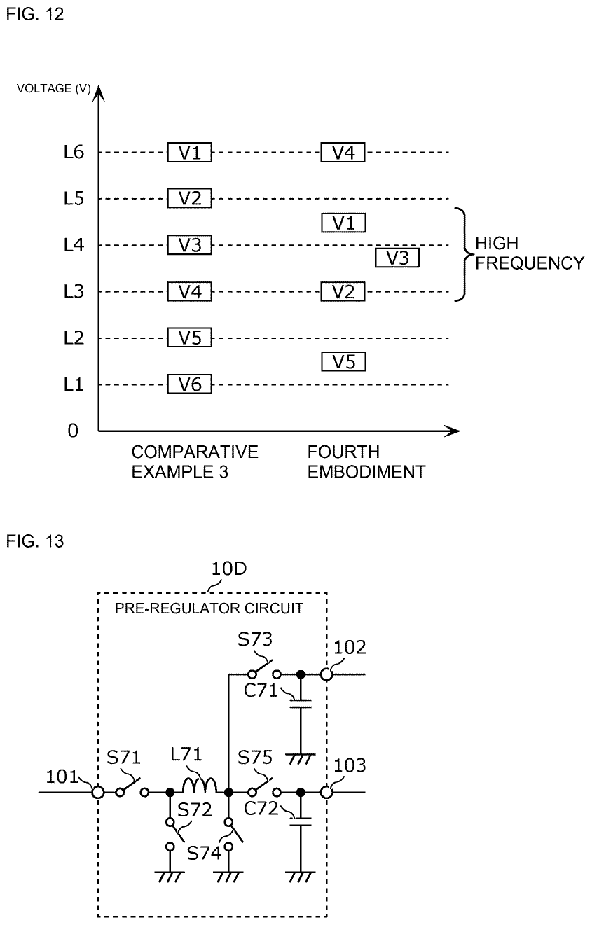

A plurality of discrete voltages that can be supplied by the tracker circuit 1C according to the present embodiment will be described with reference to FIG. 12. FIG. 12 is a diagram illustrating a plurality of discrete voltages that can be supplied in the present embodiment and comparative example 3.

In comparative example 3, six discrete voltages are generated by using a ladder switched-capacitor circuit. In this case, the six discrete voltages (V1 to V6) are arranged at uniform level intervals between level L6 and the ground level, and two voltages (V3 and V4) among the six discrete voltages (V1 to V6) are included in the high-frequency range in FIG. 12.

In contrast to this, in the present embodiment, five discrete voltages are generated by using the ladder switched-capacitor circuit 21C and the differential switched-capacitor circuit 22. In this case, the five discrete voltages (V1 to V5) are arranged at non-uniform level intervals between level L6 and the ground level, and three voltages (V1 to V3) among the five discrete voltages (V1 to V5) are included in the high-frequency range in FIG. 12.

Accordingly, in the present embodiment, the number of voltages included in the high-frequency range can be increased and the power-added efficiency can be increased as compared with comparative example 3. In the present embodiment, the total number of the plurality of discrete voltages is reduced and thus the power efficiency of the tracker circuit 1C is increased as compared with comparative example 3.

That is, in the present embodiment, the number of voltages included in the high-frequency range relative to the total number of the plurality of discrete voltages can be increased, and the power-added efficiency can be increased while an increase in the size of the tracker circuit 1C is suppressed.

### [4.3 Technical Effects]

As described above, the tracker circuit 1C according to the present embodiment includes the switched-capacitor circuit 21C configured to generate, from the first input voltage (V1), the first output voltage (V1), the second output voltage (V2) that is lower than the first output voltage (V1), the fourth output voltage (V4) that is higher than the first output voltage (V1), and the fifth output voltage (V5) that is lower than the second output voltage (V2); the switched-capacitor circuit 22 configured to generate, from the first output voltage (V1) and the second output voltage (V2), the third output voltage (V3) that is lower than the first output voltage (V1) and higher than the second output voltage (V2); and the supply modulator 30B configured to selectively output, to the PA 2, at least one of a plurality of discrete voltages including the first output voltage (V1), the second output voltage (V2), the third output voltage (V3), the fourth output voltage (V4), and the fifth output voltage (V5).

From another point of view, the tracker circuit 1C according to the present embodiment includes the switched-capacitor circuit 21C including the input terminal 211 that receives the first input voltage (V1), and the output terminals 213 to 216 that respectively output the first output voltage (V1), the second output voltage (V2), the fourth output voltage (V4), and the fifth output voltage (V5) that are generated from the first input voltage (V1), the second output voltage (V2) being lower than the first output voltage (V1), the fourth output voltage (V4) being higher than the first output voltage (V1), the fifth output voltage (V5) being lower than the second output voltage (V2); the switched-capacitor circuit 22 including the input terminals 221 and 222 respectively connected to the output terminals 213 and 214, and the output terminal 225 that outputs the third output voltage (V3) generated from the first output voltage (V1) and the second output voltage (V2), the third output voltage (V3) being lower than the first output voltage (V1) and higher than the second output voltage (V2); and the supply modulator 30B including the input terminals 301 to 305 respectively connected to the output terminals 213, 214, 225, 215, and 216, and the output terminal 306 connected to the PA 2.

Accordingly, the switched-capacitor circuit 21C generates the first output voltage (V1), the second output voltage (V2), the fourth output voltage (V4), and the fifth output voltage (V5), and furthermore the switched-capacitor circuit 22 generates the third output voltage (V3) between the first output voltage (V1) and the second output voltage (V2). Thus, the five discrete voltages (V1 to V5) can be generated at non-uniform level intervals. Thus, many discrete voltages can be generated in the range of voltages appropriate for the power that occurs with a higher frequency near the average power of an RF signal (a high-frequency range). As a result, in the D-ET mode, the voltage can be finely regulated for the power that occurs with a higher frequency, and the power-added efficiency of the PA 2 can be improved. On the contrary, voltages appropriate for the power that occurs with a lower frequency can be reduced. Thus, the total number of the plurality of discrete voltages is reduced, and thus the power efficiency of the tracker circuit 1C is increased.

For example, in the tracker circuit 1C according to the present embodiment, the switched-capacitor circuit 22 may be configured to generate, based on a difference between the first output voltage (V1) and the second output voltage (V2), the third output voltage (V3).

Accordingly, the switched-capacitor circuit 22 is configured to effectively generate the third output voltage (V3) between the first output voltage (V1) and the second output voltage (V2).

The communication device 7 according to the present embodiment includes the tracker circuit 1C, the RFIC 5 configured to process an RF signal, and the RF circuit 4 including the PA 2 and configured to transmit the RF signal between the RFIC 5 and the antenna 6.

Accordingly, an effect similar to that of the tracker circuit 1C can be implemented in the communication device 7, and power consumption can be effectively reduced.

### Fifth Exemplary Embodiment

Hereinafter, a fifth exemplary embodiment will be described. The present embodiment is different from the first and fourth embodiments mainly in that the switched-capacitor circuit in the first stage has a differential circuit configuration. Hereinafter, the present embodiment will be described with a focus on differences from the first and fourth embodiments with reference to the drawings.

The communication device 7 according to the present embodiment is similar to the communication device 7 according to the first embodiment except that a pre-regulator circuit 10D and a tracker circuit 1D are included instead of the pre-regulator circuit 10 and the tracker circuit 1, and thus the illustration and description thereof is omitted.

### [5.1 Circuit Configuration of Pre-Regulator Circuit 10D]

The circuit configuration of the pre-regulator circuit 10D will be described with reference to FIG. 13. FIG. 13 is a circuit configuration diagram of the pre-regulator circuit 10D according to the present embodiment.

FIG. 13 illustrates an exemplary circuit configuration. The pre-regulator circuit 10D can be implemented by using any of a wide variety of circuit implementations and circuit techniques. Thus, it should be appreciated that the description of the pre-regulator circuit 10D provided below is not to be construed in a limiting manner.

The pre-regulator circuit 10D includes an input terminal 101, output terminals 102 and 103, switches S71 to S75, a power inductor L71, and capacitors C71 and C72.

The output terminal 103 is a terminal for supplying an input voltage (V2) to a switched-capacitor circuit 21D. The output terminal 103 is connected to an input terminal 212 of the switched-capacitor circuit 21D outside the pre-regulator circuit 10D and is connected to the switch S75 inside the pre-regulator circuit 10D.

The switch S75 is connected between the other end of the power inductor L71 and the output terminal 103. In this connection configuration, open/close switching of the switch S75 enables switching between connection and disconnection between the other end of the power inductor L71 and the output terminal 103.

The capacitor C72 is connected between ground and a path between the switch S75 and the output terminal 103. To be specific, one of the two electrodes of the capacitor C72 is connected to the switch S75 and the output terminal 103, and the other of the two electrodes of the capacitor C72 is connected to ground.

The configuration of the pre-regulator circuit 10D illustrated in FIG. 13 is illustrative and is not restrictive. For example, one or some of the switches S71 to S75 may be replaced with a diode. A part or the entirety of the pre-regulator circuit 10D may be included in the tracker circuit 1D. The pre-regulator circuit 10D may be replaced with two pre-regulator circuits 10.

### [5.2 Circuit Configuration of Tracker Circuit 1D]

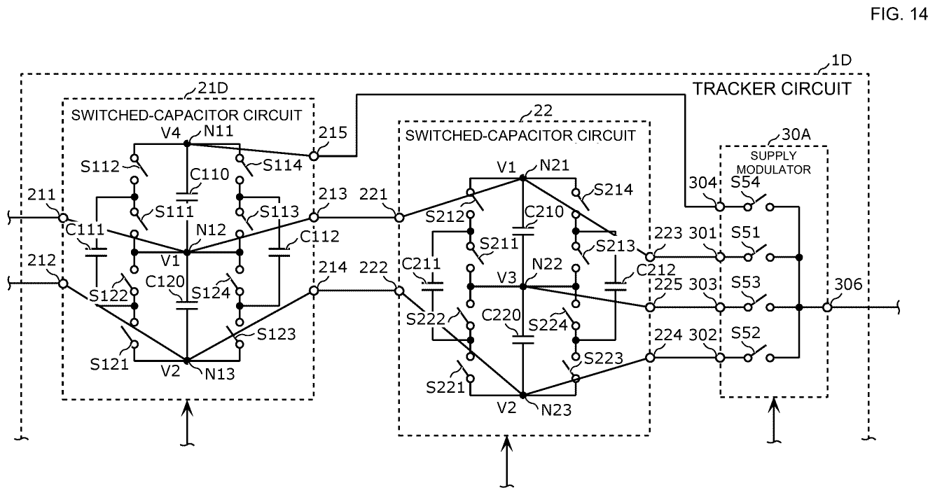

Next, the circuit configuration of the tracker circuit 1D will be described with reference to FIG. 14. FIG. 14 is a partial circuit configuration diagram of the tracker circuit 1D according to the present embodiment.

FIG. 14 illustrates an exemplary circuit configuration. The tracker circuit 1D can be implemented by using any of a wide variety of circuit implementations and circuit techniques. Thus, it should be appreciated that the description of the tracker circuit 1D provided below is not to be construed in a limiting manner.

The tracker circuit 1D is similar to the tracker circuit 1 according to the first embodiment except that the switched-capacitor circuit 21D and a supply modulator 30A are included instead of the switched-capacitor circuit 21 and the supply modulator 30. Thus, the circuit configurations of the switched-capacitor circuit 21D and the supply modulator 30A will be described below with reference to FIG. 14.

### [5.2.1 Circuit Configuration of Switched-Capacitor Circuit 21D]

The switched-capacitor circuit 21D is an example of a first switched-capacitor circuit and has a differential circuit configuration. To be specific, the switched-capacitor circuit 21D includes capacitors C110 to C112 and C120, switches S111 to S114 and S121 to S124, input terminals 211 and 212, and output terminals 213 to 215. Energy and electric charge are input from the pre-regulator circuit 10D to nodes N12 and N13 via the input terminals 211 and 212 and withdrawn from nodes N11 to N13 to the switched-capacitor circuit 22 and the supply modulator 30A via the output terminals 213 to 215.

The input terminal 211 is an example of a first input terminal and is a terminal for receiving an input voltage (V1) from the pre-regulator circuit 10D. The input terminal 211 is connected to the pre-regulator circuit 10D outside the switched-capacitor circuit 21D and is connected to the node N12 inside the switched-capacitor circuit 21D.

The input voltage (V1) is an example of a first input voltage and is supplied from the pre-regulator circuit 10D.

The input terminal 212 is an example of a seventh input terminal and is a terminal for receiving an input voltage (V2) from the pre-regulator circuit 10D. The input terminal 212 is connected to the pre-regulator circuit 10D outside the switched-capacitor circuit 21D and is connected to the node N13 inside the switched-capacitor circuit 21D.

The input voltage (V2) is an example of a second input voltage and is supplied from the pre-regulator circuit 10D.

The output terminal 213 is an example of a first output terminal and is a terminal for supplying an output voltage (V1) to the switched-capacitor circuit 22. The output terminal 213 is connected to the switched-capacitor circuit 22 outside the switched-capacitor circuit 21D and is connected to the node N12 inside the switched-capacitor circuit 21D. The output terminal 213 may be integrated with the input terminal 211.

The output voltage (V1) is an example of a first output voltage and is generated from the input voltages (V1 and V2). In the present embodiment, the output voltage (V1) is lower than an output voltage (V4) and higher than an output voltage (V2).

The output terminal 214 is an example of a second output terminal and is a terminal for supplying the output voltage (V2) to the switched-capacitor circuit 22. The output terminal 214 is connected to the switched-capacitor circuit 22 outside the switched-capacitor circuit 21D and is connected to the node N13 inside the switched-capacitor circuit 21D. The output terminal 214 may be integrated with the input terminal 212.

The output voltage (V2) is an example of a second output voltage and is generated from the input voltage (V2). In the present embodiment, the output voltage (V2) is lower than the output voltage (V1).

The output terminal 215 is an example of a fifth output terminal and is a terminal for supplying the output voltage (V4) to the supply modulator 30A. The output terminal 215 is connected to the supply modulator 30A outside the switched-capacitor circuit 21D and is connected to the node N11 inside the switched-capacitor circuit 21D.

The output voltage (V4) is an example of a fourth output voltage and is generated from the input voltages (V1 and V2). In the present embodiment, the output voltage (V4) is equal to the input voltage (V1) and higher than the output voltage (V1).

The capacitors C111 and C112 are flying capacitors and are configured to raise and/or lower the input voltages (V1 and V2) supplied from the pre-regulator circuit 10D. To be more specific, the capacitors C111 and C112 cause electric charge to move between the capacitors C111 and C112 and the nodes N11 to N13 so that the voltages V1, V2, and V4 satisfying (V4−V1):(V1−V2)=1:1 and V4>V1>V2 are maintained at the three nodes N11 to N13.

The capacitors C110 and C120 are configured as smoothing capacitors that hold and smooth the output voltages (V1, V2, and V4) at the nodes N11 to N13.

As in the first embodiment, a first set of switches including the switches S112, S113, S122, and S123 and a second set of switches including the switches S111, S114, S121, and S124 are switched between open and close in a complementary manner based on a control signal from the digital control circuit 60. To be specific, in a first phase, the switches in the first set are closed whereas the switches in the second set are opened. On the other hand, in a second phase, the switches in the first set are opened whereas the switches in the second set are closed.

As a result of operating in the above-described manner, the switched-capacitor circuit 21D is configured to maintain substantially equal voltages across each of the capacitors C110 and C120. To be specific, the voltages V1, V2, and V4 (voltages with respect to a ground potential) satisfying (V4−V1):(V1−V2)=1:1 are maintained at the three nodes labeled V1, V2, and V4.

It is again noted that (V4−V1):(V1−V2) is not limited to 1:1 and may be designed to have any ratio (for example, 2:1, 3:1, 3:2, 1:2, or 2:3) according to alternative aspects.

### [5.2.2 Circuit Configuration of Supply Modulator 30A]

Next, the circuit configuration of the supply modulator 30A will be described with reference to FIG. 14. The supply modulator 30A includes input terminals 301 to 304, switches S51 to S54, and an output terminal 306.

The supply modulator 30A according to the present embodiment is similar to the supply modulator 30A according to the second embodiment except that the connection of the input terminal 304 outside the supply modulator 30A is different. Thus, the description of the input terminal 304 will be provided, and the description of the other part will be omitted.

The input terminal 304 is an example of an eighth input terminal and is a terminal for receiving the output voltage (V4) generated by the switched-capacitor circuit 21D. The input terminal 304 is connected to the output terminal 215 of the switched-capacitor circuit 21D outside the supply modulator 30A and is connected to the switch S54 inside the supply modulator 30A.

### [5.3 a Plurality of Discrete Voltages]

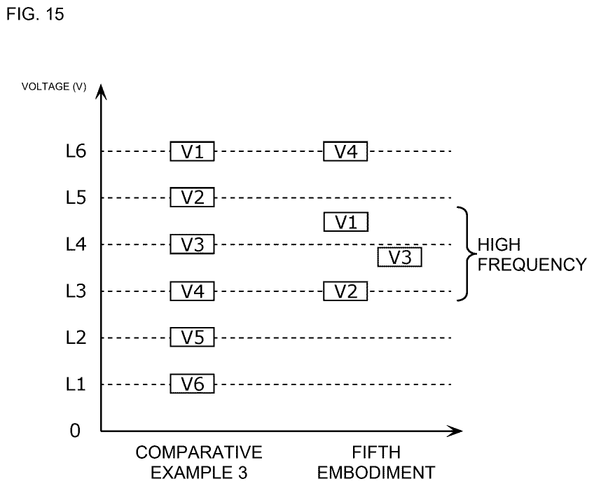

A plurality of discrete voltages that can be supplied by the tracker circuit 1D according to the present embodiment will be described with reference to FIG. 15. FIG. 15 is a diagram illustrating a plurality of discrete voltages that can be supplied in the present embodiment and comparative example 3.

In comparative example 3, six discrete voltages are generated by using a ladder switched-capacitor circuit. In this case, the six discrete voltages (V1 to V6) are arranged at uniform level intervals between level L6 and the ground level, and two voltages (V3 and V4) among the six discrete voltages (V1 to V6) are included in the high-frequency range in FIG. 15.

In contrast to this, in the present embodiment, four discrete voltages are generated by using the two differential switched-capacitor circuits 21D and 22. In this case, the four discrete voltages (V1 to V4) are arranged at non-uniform level intervals between level L6 and the ground level, and three voltages (V1 to V3) among the four discrete voltages (V1 to V4) are included in the high-frequency range in FIG. 15.

Accordingly, in the present embodiment, the number of voltages included in the high-frequency range can be increased and the power-added efficiency can be increased as compared with comparative example 3. In the present embodiment, the total number of the plurality of discrete voltages is reduced and thus the power efficiency of the tracker circuit 1D is increased as compared with comparative example 3.

That is, in the present embodiment, the number of voltages included in the high-frequency range relative to the total number of the plurality of discrete voltages can be increased, and the power-added efficiency can be increased while an increase in the size of the tracker circuit 1D is suppressed.

### [5.4 Technical Effects]

As described above, the tracker circuit 1D according to the present embodiment includes the switched-capacitor circuit 21D configured to generate, from the first input voltage (V1) and the second input voltage (V2), the first output voltage (V1), the second output voltage (V2) that is lower than the first output voltage (V1), and the fourth output voltage (V4) that is higher than the first output voltage (V1); the switched-capacitor circuit 22 configured to generate, from the first output voltage (V1) and the second output voltage (V2), the third output voltage (V3) that is lower than the first output voltage (V1) and higher than the second output voltage (V2); and the supply modulator 30A configured to selectively output, to the PA 2, at least one of a plurality of discrete voltages including the first output voltage (V1), the second output voltage (V2), the third output voltage (V3), and the fourth output voltage (V4).

From another point of view, the tracker circuit 1D according to the present embodiment includes the switched-capacitor circuit 21D including the input terminals 211 and 212 that respectively receive the first input voltage (V1) and the second input voltage (V2), and the output terminals 213, 214, and 215 that respectively output the first output voltage (V1), the second output voltage (V2), and the fourth output voltage (V4) that are generated from the first input voltage (V1) and the second input voltage (V2), the second output voltage (V2) being lower than the first output voltage (V1), the fourth output voltage (V4) being higher than the first output voltage (V1); the switched-capacitor circuit 22 including the input terminals 221 and 222 respectively connected to the output terminals 213 and 214, and the output terminal 225 that outputs the third output voltage (V3) generated from the first output voltage (V1) and the second output voltage (V2), the third output voltage (V3) being lower than the first output voltage (V1) and higher than the second output voltage (V2); and the supply modulator 30A including the input terminals 301 to 304 respectively connected to the output terminals 213, 214, 225, and 215, and the output terminal 306 connected to the PA 2.

Accordingly, the switched-capacitor circuit 21D generates the first output voltage (V1), the second output voltage (V2), and the fourth output voltage (V4) from the first input voltage (V1) and the second input voltage (V2), and furthermore the switched-capacitor circuit 22 generates the third output voltage (V3) between the first output voltage (V1) and the second output voltage (V2). Thus, the four discrete voltages (V1 to V4) can be generated at non-uniform level intervals. Thus, many discrete voltages can be generated in the range of voltages appropriate for the power that occurs with a higher frequency near the average power of an RF signal (a high-frequency range). As a result, in the D-ET mode, the voltage can be finely regulated for the power that occurs with a higher frequency, and the power-added efficiency of the PA 2 can be improved. On the contrary, voltages appropriate for the power that occurs with a lower frequency can be reduced. Thus, the total number of the plurality of discrete voltages is reduced, and thus the power efficiency of the tracker circuit 1D is increased.

For example, in the tracker circuit 1D according to the present embodiment, the switched-capacitor circuit 21D may be configured to generate, based on a difference between the first input voltage (V1) and the second input voltage (V2), the first output voltage (V1), the second output voltage (V2), and the fourth output voltage (V4).

Accordingly, as a result of changing the difference between the first input voltage (V1) and the second input voltage (V2), the first output voltage (V1), the second output voltage (V2), and the fourth output voltage (V4) can be changed, and the levels and intervals of the first output voltage (V1), the second output voltage (V2), and the fourth output voltage (V4) can be changed more flexibly.

For example, in the tracker circuit 1D according to the present embodiment, the switched-capacitor circuit 22 may be configured to generate, based on a difference between the first output voltage (V1) and the second output voltage (V2), the third output voltage (V3).

Accordingly, the switched-capacitor circuit 22 is configured to effectively generate the third output voltage (V3) between the first output voltage (V1) and the second output voltage (V2).

The communication device 7 according to the present embodiment includes the tracker circuit 1D, the RFIC 5 configured to process an RF signal, and the RF circuit 4 including the PA 2 and configured to transmit the RF signal between the RFIC 5 and the antenna 6.

Accordingly, an effect similar to that of the tracker circuit 1D can be implemented in the communication device 7, and power consumption can be effectively reduced.

### Sixth Exemplary Embodiment

Hereinafter, a sixth exemplary embodiment will be described. The present embodiment is different from the first embodiment mainly in that the tracker circuit includes a third switched-capacitor circuit in addition to the two switched-capacitor circuits. Hereinafter, the present embodiment will be described with a focus on differences from the first embodiment with reference to the drawings.

The communication device 7 according to the present embodiment is similar to the communication device 7 according to the first embodiment except that a tracker circuit 1E is included instead of the tracker circuit 1, and thus the illustration and description thereof is omitted.

### [6.1 Circuit Configuration of Tracker Circuit 1E]

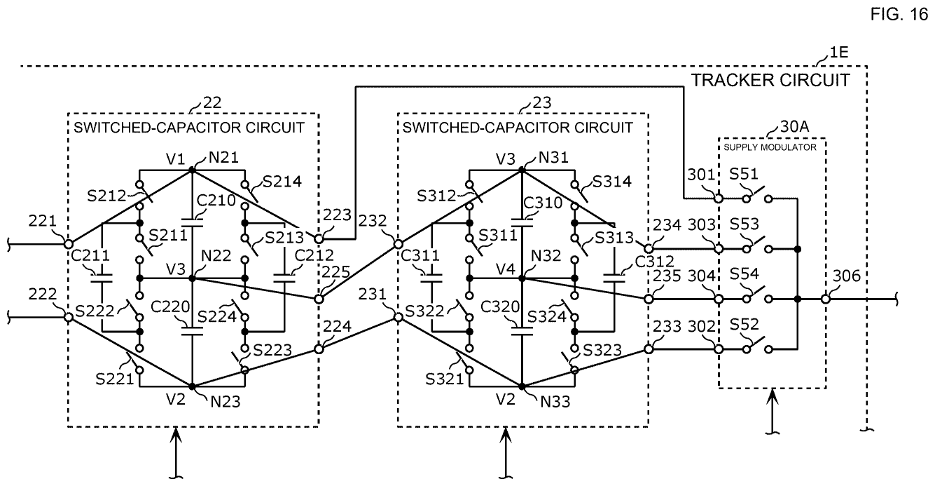

Next, the circuit configuration of the tracker circuit 1E will be described with reference to FIG. 16. FIG. 16 is a partial circuit configuration diagram of the tracker circuit 1E according to the present embodiment.

FIG. 16 illustrates an exemplary circuit configuration. The tracker circuit 1E can be implemented by using any of a wide variety of circuit implementations and circuit techniques. Thus, it should be appreciated that the description of the tracker circuit 1E provided below is not to be construed in a limiting manner.

The tracker circuit 1E is similar to the tracker circuit 1 according to the first embodiment except that a supply modulator 30A is included instead of the supply modulator 30 and that a switched-capacitor circuit 23 is included in addition to the switched-capacitor circuits 21 and 22. Thus, the circuit configurations of the switched-capacitor circuit 23 and the supply modulator 30A will be described below with reference to FIG. 16.

### [6.1.1 Circuit Configuration of Switched-Capacitor Circuit 23]

Next, the circuit configuration of the switched-capacitor circuit 23 will be described with reference to FIG. 16. The switched-capacitor circuit 23 has a differential circuit configuration. To be specific, the switched-capacitor circuit 23 includes capacitors C310 to C312 and C320, switches S311 to S314 and S321 to S324, input terminals 231 and 232, and output terminals 233 to 235. Energy and electric charge are input from the switched-capacitor circuit 22 to nodes N31 and N33 via the input terminals 231 and 232 and withdrawn from nodes N31 to N33 to the supply modulator 30A via the output terminals 233 to 235.

The input terminal 231 is an example of a seventh input terminal and is a terminal for receiving an output voltage (V2) from the switched-capacitor circuit 22. The input terminal 231 is connected to the switched-capacitor circuit 22 outside the switched-capacitor circuit 23 and is connected to the node N33 inside the switched-capacitor circuit 23.

The input terminal 232 is an example of an eighth input terminal and is a terminal for receiving an output voltage (V3) from the switched-capacitor circuit 22. The input terminal 232 is connected to the switched-capacitor circuit 22 outside the switched-capacitor circuit 23 and is connected to the node N31 inside the switched-capacitor circuit 23.

The output terminal 233 is a terminal for supplying an output voltage (V2) to the supply modulator 30A. The output terminal 233 is connected to the supply modulator 30A outside the switched-capacitor circuit 23 and is connected to the node N33 inside the switched-capacitor circuit 23. The output terminal 233 may be omitted from the switched-capacitor circuit 23 and instead integrated with the input terminal 231 according to an exemplary aspect.

The output terminal 234 is a terminal for supplying an output voltage (V3) to the supply modulator 30A. The output terminal 234 is connected to the supply modulator 30A outside the switched-capacitor circuit 23 and is connected to the node N31 inside the switched-capacitor circuit 23. The output terminal 234 may be omitted from the switched-capacitor circuit 23 and instead integrated with the input terminal 232 according to an exemplary aspect.

The output terminal 235 is an example of a fifth output terminal and is a terminal for supplying an output voltage (V4) to the supply modulator 30A. The output terminal 235 is connected to the supply modulator 30A outside the switched-capacitor circuit 23 and is connected to the node N32 inside the switched-capacitor circuit 23.

The output voltage (V4) is an example of a fourth output voltage and is generated from the output voltages (V2 and V3). In the present embodiment, the output voltage (V4) is lower than the output voltage (V3) and higher than the output voltage (V2).

The capacitors C311 and C312 are flying capacitors and are used to raise and/or lower the output voltages (V2 and V3) supplied from the switched-capacitor circuit 22. To be more specific, the capacitors C311 and C312 cause electric charge to move between the capacitors C311 and C312 and the nodes N31 to N33 so that the voltages V2 to V4 satisfying (V3−V4):(V4−V2)=1:1 and V3>V4>V2 are maintained at the three nodes N31 to N33.

One of the two electrodes of the capacitor C311 is connected to one end of the switch S311 and one end of the switch S312. The other of the two electrodes of the capacitor C311 is connected to one end of the switch S321 and one end of the switch S322.

One of the two electrodes of the capacitor C312 is connected to one end of the switch S313 and one end of the switch S314. The other of the two electrodes of the capacitor C312 is connected to one end of the switch S323 and one end of the switch S324.

The capacitors C311 and C312 can be charged and discharged in a complementary manner as a result of a first phase and a second phase being repeated.

To be specific, in the first phase, the switches S312, S313, S322, and S323 are closed, whereas the switches S311, S314, S321, and S324 are opened. Accordingly, the one of the two electrodes of the capacitor C311 is connected to the node N31, the other of the two electrodes of the capacitor C311 and the one of the two electrodes of the capacitor C312 are connected to the node N32, and the other of the two electrodes of the capacitor C312 is connected to the node N33.

On the other hand, in the second phase, the switches S312, S313, S322, and S323 are opened, whereas the switches S311, S314, S321, and S324 are closed. Accordingly, the one of the two electrodes of the capacitor C312 is connected to the node N31, the other of the two electrodes of the capacitor C312 and the one of the two electrodes of the capacitor C311 are connected to the node N32, and the other of the two electrodes of the capacitor C311 is connected to the node N33.

As a result of the first phase and the second phase being repeated, for example, when one of the capacitors C311 and C312 is charged through the node N31, the other of the capacitors C311 and C312 can be discharged to the capacitor C320. In short, the capacitors C311 and C312 can be charged and discharged in a complementary manner. The capacitors C310 and C320 are configured as smoothing capacitors that hold and smooth the output voltages (V3, V4, and V2) at the nodes N31 to N33.

The capacitor C310 is connected between the nodes N31 and N32. To be specific, one of the two electrodes of the capacitor C310 is connected to the node N31. On the other hand, the other of the two electrodes of the capacitor C310 is connected to the node N32.

The capacitor C320 is connected between the nodes N32 and N33. To be specific, one of the two electrodes of the capacitor C320 is connected to the node N32. On the other hand, the other of the two electrodes of the capacitor C320 is connected to the node N33.

The switch S311 is connected between the capacitor C311 and the node N32. To be specific, the one end of the switch S311 is connected to the one of the two electrodes of the capacitor C311. On the other hand, the other end of the switch S311 is connected to the node N32.

The switch S312 is connected between the capacitor C311 and the node N31. To be specific, the one end of the switch S312 is connected to the one of the two electrodes of the capacitor C311. On the other hand, the other end of the switch S312 is connected to the node N31.

The switch S321 is connected between the capacitor C311 and the node N33. To be specific, the one end of the switch S321 is connected to the other of the two electrodes of the capacitor C311. On the other hand, the other end of the switch S321 is connected to the node N33.

The switch S322 is connected between the capacitor C311 and the node N32. To be specific, the one end of the switch S322 is connected to the other of the two electrodes of the capacitor C311. On the other hand, the other end of the switch S322 is connected to the node N32.

The switch S313 is connected between the capacitor C312 and the node N32. To be specific, the one end of the switch S313 is connected to the one of the two electrodes of the capacitor C312. On the other hand, the other end of the switch S313 is connected to the node N32. That is, the other end of the switch S313 is connected to the other end of the switch S311 and the other end of the switch S322.

The switch S314 is connected between the capacitor C312 and the node N31. To be specific, the one end of the switch S314 is connected to the one of the two electrodes of the capacitor C312. On the other hand, the other end of the switch S314 is connected to the node N31. That is, the other end of the switch S314 is connected to the other end of the switch S312.

The switch S323 is connected between the capacitor C312 and the node N33. To be specific, the one end of the switch S323 is connected to the other of the two electrodes of the capacitor C312. On the other hand, the other end of the switch S323 is connected to the node N33. That is, the other end of the switch S323 is connected to the other end of the switch S321.

The switch S324 is connected between the capacitor C312 and the node N32. To be specific, the one end of the switch S324 is connected to the other of the two electrodes of the capacitor C312. On the other hand, the other end of the switch S324 is connected to the node N32. That is, the other end of the switch S324 is connected to the other end of the switch S311, the other end of the switch S322, and the other end of the switch S313.

A first set of switches including the switches S312, S313, S322, and S323 and a second set of switches including the switches S311, S314, S321, and S324 are switched between open and close in a complementary manner based on a control signal from the digital control circuit 60. To be specific, in the first phase, the switches in the first set are closed whereas the switches in the second set are opened. On the other hand, in the second phase, the switches in the first set are opened whereas the switches in the second set are closed.

For example, in one of the first phase and the second phase, charging from the capacitor C311 to the capacitors C310 and C320 is performed, and in the other of the first phase and the second phase, charging from the capacitor C312 to the capacitors C310 and C320 is performed. In other words, because the capacitors C310 and C320 are constantly charged from the capacitor C311 or the capacitor C312, the nodes N31 to N33 are rapidly replenished with electric charge even when currents rapidly flow from the nodes N31 to N33 to the supply modulator 30A. Thus, potential variations at the nodes N31 to N33 can be suppressed.

As a result of operating in the above-described manner, the switched-capacitor circuit 23 is configured to capable of maintaining substantially equal voltages across each of the capacitors C310 and C320. To be specific, the voltages V2 to V4 (voltages with respect to a ground potential) satisfying (V3−V4):(V4−V2)=1:1 are maintained at the three nodes labeled V2 to V4.

It is again noted that (V3−V4):(V4−V2) is not limited to 1:1 and may be designed to have any ratio (for example, 2:1, 3:1, 3:2, 1:2, or 2:3) according to alternative exemplary aspects.

### [6.1.2 Circuit Configuration of Supply Modulator 30A]

Next, the circuit configuration of the supply modulator 30A will be described with reference to FIG. 16. The supply modulator 30A includes input terminals 301 to 304, switches S51 to S54, and an output terminal 306.

The supply modulator 30A according to the present embodiment is similar to the supply modulator 30A according to the second embodiment except that the connections of the input terminals 301 to 304 outside the supply modulator 30A are different. Thus, the description of the input terminals 301 to 304 will be provided, and the description of the other part will be omitted.

The input terminals 301 to 304 are an example of a fourth input terminal, an example of a fifth input terminal, an example of a sixth input terminal, and an example of a ninth input terminal, respectively, and are terminals for receiving the output voltages (V1 to V4) generated by the switched-capacitor circuits 21 to 23.

The input terminal 301 is an example of a fourth input terminal and is a terminal for receiving the output voltage (V1) generated by the switched-capacitor circuit 22. The input terminal 301 is connected to the output terminal 223 of the switched-capacitor circuit 22 outside the supply modulator 30A and is connected to the switch S51 inside the supply modulator 30A.

The input terminal 302 is an example of a fifth input terminal and is a terminal for receiving the output voltage (V2) generated by the switched-capacitor circuit 23. The input terminal 302 is connected to the output terminal 233 of the switched-capacitor circuit 23 outside the supply modulator 30A and is connected to the switch S52 inside the supply modulator 30A.

The input terminal 303 is an example of a sixth input terminal and is a terminal for receiving the output voltage (V3) generated by the switched-capacitor circuit 23. The input terminal 303 is connected to the output terminal 234 of the switched-capacitor circuit 23 outside the supply modulator 30A and is connected to the switch S53 inside the supply modulator 30A.

The input terminal 304 is an example of an ninth input terminal and is a terminal for receiving the output voltage (V4) generated by the switched-capacitor circuit 23. The input terminal 304 is connected to the output terminal 235 of the switched-capacitor circuit 23 outside the supply modulator 30A and is connected to the switch S54 inside the supply modulator 30A.

### [6.2 a Plurality of Discrete Voltages]

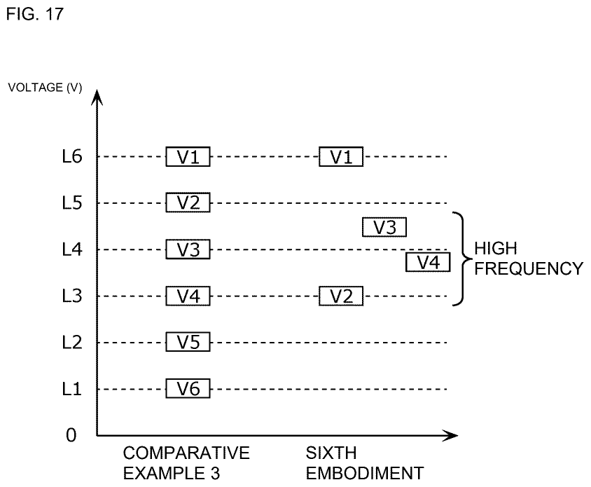

A plurality of discrete voltages that can be supplied by the tracker circuit 1E according to the present embodiment will be described with reference to FIG. 17. FIG. 17 is a diagram illustrating a plurality of discrete voltages that can be supplied in the present embodiment and comparative example 3.

In comparative example 3, six discrete voltages are generated by using a ladder switched-capacitor circuit. In this case, the six discrete voltages (V1 to V6) are arranged at uniform level intervals between level L6 and the ground level, and two voltages (V3 and V4) among the six discrete voltages (V1 to V6) are included in the high-frequency range in FIG. 17.

In contrast to this, in the present embodiment, four discrete voltages are generated by using the one ladder switched-capacitor circuit 21 and the two differential switched-capacitor circuits 22 and 23. In this case, the four discrete voltages (V1 to V4) are arranged at non-uniform level intervals between level L6 and the ground level, and three voltages (V2 to V4) among the four discrete voltages (V1 to V4) are included in the high-frequency range in FIG. 17.

Accordingly, in the present embodiment, the number of voltages included in the high-frequency range can be increased and the power-added efficiency can be increased as compared with comparative example 3. In the present embodiment, the total number of the plurality of discrete voltages is reduced and thus the power efficiency of the tracker circuit 1E is increased as compared with comparative example 3.

That is, in the present embodiment, the number of voltages included in the high-frequency range relative to the total number of the plurality of discrete voltages can be increased, and the power-added efficiency can be increased while an increase in the size of the tracker circuit 1E is suppressed.

### [6.3 Technical Effects]

As described above, the tracker circuit 1E according to the present embodiment includes the switched-capacitor circuit 21 configured to generate, from the first input voltage (V1), the first output voltage (V1) and the second output voltage (V2) that is lower than the first output voltage (V1); the switched-capacitor circuit 22 configured to generate, from the first output voltage (V1) and the second output voltage (V2), the third output voltage (V3) that is lower than the first output voltage (V1) and higher than the second output voltage (V2); the switched-capacitor circuit 23 configured to generate, from the second output voltage (V2) and the third output voltage (V3), the fourth output voltage (V4) that is higher than the second output voltage (V2) and lower than the third output voltage (V3); and the supply modulator 30A configured to selectively output, to the PA 2, at least one of a plurality of discrete voltages including the first output voltage (V1), the second output voltage (V2), the third output voltage (V3), and the fourth output voltage (V4).

From another point of view, the tracker circuit 1E according to the present embodiment includes the switched-capacitor circuit 21 including the input terminal 211 that receives the first input voltage (V1), and the output terminals 213 and 214 that respectively output the first output voltage (V1) and the second output voltage (V2) that are generated from the first input voltage (V1), the second output voltage (V2) being lower than the first output voltage (V1); the switched-capacitor circuit 22 including the input terminals 221 and 222 respectively connected to the output terminals 213 and 214, and the output terminal 225 that outputs the third output voltage (V3) generated from the first output voltage (V1) and the second output voltage (V2), the third output voltage (V3) being lower than the first output voltage (V1) and higher than the second output voltage (V2); the switched-capacitor circuit 23 including the input terminals 231 and 232 respectively connected to the output terminals 214 and 225, and the output terminal 235 that outputs the fourth output voltage (V4) generated from the second output voltage (V2) and the third output voltage (V3), the fourth output voltage (V4) being higher than the second output voltage (V2) and lower than the third output voltage (V3); and the supply modulator 30A including the input terminals 301 to 304 respectively connected to the output terminals 213, 214, 225, and 235, and the output terminal 306 connected to the PA 2.

Accordingly, the switched-capacitor circuit 21 generates the first output voltage (V1) and the second output voltage (V2), the switched-capacitor circuit 22 generates the third output voltage (V3) between the first output voltage (V1) and the second output voltage (V2), and the switched-capacitor circuit 23 generates the fourth output voltage (V4) between the second output voltage (V2) and the third output voltage (V3). Thus, the four discrete voltages (V1 to V4) can be generated at non-uniform level intervals. Thus, many discrete voltages can be generated in the range of voltages appropriate for the power that occurs with a higher frequency near the average power of an RF signal (a high-frequency range). As a result, in the D-ET mode, the voltage can be finely regulated for the power that occurs with a higher frequency, and the power-added efficiency of the PA 2 can be improved. On the contrary, voltages appropriate for the power that occurs with a lower frequency can be reduced. Thus, the total number of the plurality of discrete voltages is reduced, and thus the power efficiency of the tracker circuit 1E is increased.

For example, in the tracker circuit 1E according to the present embodiment, the switched-capacitor circuit 23 may be configured to generate, based on a difference between the second output voltage (V2) and the third output voltage (V3), the fourth output voltage (V4).

Accordingly, the switched-capacitor circuit 23 is configured to effectively generate the fourth output voltage (V4) between the second output voltage (V2) and the third output voltage (V3).

For example, in the tracker circuit 1E according to the present embodiment, the switched-capacitor circuit 22 may be configured to generate, based on a difference between the first output voltage (V1) and the second output voltage (V2), the third output voltage (V3).

Accordingly, the switched-capacitor circuit 22 is configured to effectively generate the third output voltage (V3) between the first output voltage (V1) and the second output voltage (V2).

The communication device 7 according to the present embodiment includes the tracker circuit 1E, the RFIC 5 configured to process an RF signal, and the RF circuit 4 including the PA 2 and configured to transmit the RF signal between the RFIC 5 and the antenna 6.

Accordingly, an effect similar to that of the tracker circuit 1E can be implemented in the communication device 7, and power consumption can be effectively reduced.

### Additional Exemplary Embodiments

The exemplary tracker circuit, the communication device, and the voltage supply method have been described above based on the embodiments. It is noted that the tracker circuit, the communication device, and the voltage supply method according to the exemplary aspects of the present disclosure are not limited to the above embodiments. Another embodiment implemented by combining any constituent elements in the above embodiments, modifications obtained by applying various changes conceived by those skilled in the art to the above embodiments without departing from the gist of the present disclosure, and various devices including the above-described tracker circuit are also included in the exemplary aspects of the present disclosure.

For example, in the circuit configurations of the various circuits according to the above embodiments, another circuit element, another wiring line, and the like may be inserted to a path connecting individual circuit elements and a signal path disclosed in the drawings as would be appreciated to one skilled in the art. For example, an inductor and/or a capacitor may be inserted between a tracker circuit and a PA.

In the switched-capacitor circuits according to the above embodiments, the connection relationship between an input terminal and a node may be changed. For example, in the first embodiment, the input terminal 211 may be connected to the node N12 instead of the node N11. Also in this case, an effect similar to that of the first embodiment can be obtained.

The tracker circuits according to the above embodiments may include a plurality of supply modulators. In this case, the tracker circuits are configured to supply different voltages to a plurality of PAs.

The exemplary aspects of the present disclosure can be widely used, as a tracker circuit for supplying a voltage to a power amplifier, in communication devices such as mobile phones.

### REFERENCE SIGNS LIST

1, 1A, 1B, 1C, 1D, 1E tracker circuit
2 power amplifier
3 filter
4 radio frequency circuit
5 RFIC
6 antenna
7 communication device
10, 10D pre-regulator circuit
21, 21C, 21D, 22, 22A, 22B, 23 switched-capacitor circuit
30, 30A, 30B supply modulator
50 DC power source
60 digital control circuit
61 first controller
62 second controller
101, 211, 212, 221, 222, 231, 232, 301, 302, 303, 304, 305 input terminal
102, 103, 213, 214, 215, 216, 223, 224, 225, 226, 227, 233, 234, 235, 306 output terminal
601, 602, 603, 604 control terminal

1. A tracker circuit comprising:
a first switched-capacitor circuit configured to generate, from a first input voltage, a first output voltage and a second output voltage that is lower than the first output voltage;
a second switched-capacitor circuit configured to generate, from the first output voltage and the second output voltage, a third output voltage that is lower than the first output voltage and higher than the second output voltage; and
a supply modulator configured to selectively output, to a power amplifier, at least one discrete voltage of a plurality of discrete voltages that includes the first output voltage, the second output voltage, and the third output voltage.

2. The tracker circuit according to claim 1, wherein:
the second switched-capacitor circuit is further configured to generate, from the first output voltage and the second output voltage, a fourth output voltage that is lower than the third output voltage and higher than the second output voltage, and
the plurality of discrete voltages further includes the fourth output voltage.

3. The tracker circuit according to claim 2, wherein:
the second switched-capacitor circuit is further configured to generate, from the first output voltage and the second output voltage, a fifth output voltage that is lower than the fourth output voltage and higher than the second output voltage, and
the plurality of discrete voltages further includes the fifth output voltage.

4. The tracker circuit according to claim 1, wherein:
the first switched-capacitor circuit is further configured to generate, from the first input voltage, a fourth output voltage that is higher than the first output voltage and a fifth output voltage that is lower than the second output voltage, and
the plurality of discrete voltages further includes the fourth output voltage and the fifth output voltage.

5. The tracker circuit according to claim 1, wherein:
the first switched-capacitor circuit is configured to generate, from the first input voltage and a second input voltage, the first output voltage, the second output voltage, and a fourth output voltage that is higher than the first output voltage, and
the plurality of discrete voltages further includes the fourth output voltage.

6. The tracker circuit according to claim 5, wherein the first switched-capacitor circuit is configured to generate, based on a difference between the first input voltage and the second input voltage, each of the first output voltage, the second output voltage, and the fourth output voltage.

7. The tracker circuit according to claim 1, further comprising:
a third switched-capacitor circuit configured to generate, from the second output voltage and the third output voltage, a fourth output voltage that is higher than the second output voltage and lower than the third output voltage,
wherein the plurality of discrete voltages further includes the fourth output voltage.

8. The tracker circuit according to claim 7, wherein the third switched-capacitor circuit is configured to generate, based on a difference between the second output voltage and the third output voltage, the fourth output voltage.

9. The tracker circuit according to claim 1, wherein the second switched-capacitor circuit is configured to generate, based on a difference between the first output voltage and the second output voltage, the third output voltage.

10. A communication device comprising:
the tracker circuit according to claim 1;
a signal processing circuit configured to process a radio frequency signal; and
a radio frequency circuit including the power amplifier and configured to transmit the radio frequency signal between the signal processing circuit and an antenna.

11. A tracker circuit comprising:
a first switched-capacitor circuit including:
a first input terminal configured to receive a first input voltage, and
a first output terminal and a second output terminal that are configured to output a first output voltage and a second output voltage, respectively, that are generated from the first input voltage, the second output voltage being lower than the first output voltage;
a second switched-capacitor circuit including:
a second input terminal and a third input terminal respectively connected to the first output terminal and the second output terminal, and
a third output terminal configured to output a third output voltage generated from the first output voltage and the second output voltage, the third output voltage being lower than the first output voltage and higher than the second output voltage; and
a supply modulator including:
a fourth input terminal, a fifth input terminal, and a sixth input terminal connected to the first output terminal, the second output terminal, and the third output terminal, respectively, and
a fourth output terminal connected to a power amplifier.

12. The tracker circuit according to claim 11, wherein:
the second switched-capacitor circuit further includes a fifth output terminal configured to output a fourth output voltage generated from the first output voltage and the second output voltage, the fourth output voltage being higher than the second output voltage and lower than the third output voltage, and
the supply modulator further includes a seventh input terminal connected to the fifth output terminal.

13. The tracker circuit according to claim 12, wherein:
the second switched-capacitor circuit further includes a sixth output terminal configured to output a fifth output voltage generated from the first output voltage and the second output voltage, the fifth output voltage being higher than the second output voltage and lower than the fourth output voltage, and
the supply modulator further includes an eighth input terminal connected to the sixth output terminal.

14. The tracker circuit according to claim 11, wherein:
the first switched-capacitor circuit further includes a fifth output terminal and a sixth output terminal that are configured to output a fourth output voltage and a fifth output voltage, respectively, that are generated from the first input voltage, the fourth output voltage being higher than the first output voltage, and the fifth output voltage being lower than the second output voltage, and
the supply modulator further includes a seventh input terminal and an eighth input terminal connected to the fifth output terminal and the sixth output terminal, respectively.

15. The tracker circuit according to claim 11, wherein:
the first switched-capacitor circuit further includes:
a seventh input terminal configured to receive a second input voltage, and
a fifth output terminal configured to output a fourth output voltage generated from the first input voltage and the second input voltage, the fourth output voltage being higher than the first output voltage, and
the supply modulator further includes an eighth input terminal connected to the fifth output terminal.

16. The tracker circuit according to claim 11, further comprising:
a third switched-capacitor circuit including:
a seventh input terminal and an eighth input terminal connected to the second output terminal and the third output terminal, respectively, and
a fifth output terminal configured to output a fourth output voltage generated from the second output voltage and the third output voltage, the fourth output voltage being higher than the second output voltage and lower than the third output voltage,
wherein the supply modulator further includes a ninth input terminal connected to the fifth output terminal.

17. A communication device comprising:
the tracker circuit according to claim 11;
a signal processing circuit configured to process a radio frequency signal; and
a radio frequency circuit including the power amplifier and configured to transmit the radio frequency signal between the signal processing circuit and an antenna.

18. A voltage supply method comprising:
generating, by a first switched-capacitor circuit, a first output voltage and a second output voltage from an input voltage;
generating, by a second switched-capacitor circuit, a third output voltage from the first output voltage and the second output voltage, the third output voltage being lower than the first output voltage and higher than the second output voltage; and
selectively supplying, to a power amplifier, at least one discrete voltage of a plurality of discrete voltages that includes the first output voltage, the second output voltage, and the third output voltage.

19. The voltage supply method according to claim 18, further comprising:
generating, by the second switched-capacitor circuit and based on the first output voltage and the second output voltage, a fourth output voltage that is lower than the third output voltage and higher than the second output voltage,
wherein the plurality of discrete voltages further includes the fourth output voltage.

20. The voltage supply method according to claim 19, further comprising:
generating, by the second switched-capacitor circuit and from the first output voltage and the second output voltage, a fifth output voltage that is lower than the fourth output voltage and higher than the second output voltage,
wherein the plurality of discrete voltages further includes the fifth output voltage.
